(19) United States
(12) Patent Application Publication
(10) Pub. No.: US 2026/0182069 A1
(43) Pub. Date: Jun. 25, 2026

(54) LIGHT DETECTING DEVICE AND MULTI-LAYERED SUBSTRATE

(71) Applicant: SONY SEMICONDUCTOR SOLUTIONS CORPORATION, KANAGAWA (JP)

(72) Inventors: Kiichi ISHIKAWA, KANAGAWA (JP); Hajime YAMAGISHI, KANAGAWA (JP)

(21) Appl. No.: 19/126,777

(22) PCT Filed: Oct. 30, 2023
(86) PCT No.: PCT/JP2023/039118

§ 371 Date: May 2, 2025

(30) Foreign Application Priority Data
Nov. 10, 2022 (JP) 2022-180490

(51) Int. Cl. H10F 39/00; H10W 90/00

(52) U.S. Cl. CPC H10F 39/811; H10W 90/724; H10W 90/734

(57) ABSTRACT

A light detecting device and a multi-layered substrate that can prevent degradation of characteristics are provided. The light detecting device includes a multi-layered section having a first substrate section, a second substrate section, and a third substrate section, multiple through via units that are provided in the multi-layered section and electrically connect a first circuit provided at the second substrate section and a second circuit provided at the third substrate section to each other, and multiple dummy via units that are provided in the multi-layered section, are insulated from both the first circuit and the second circuit, and are electrically fixed at a floating or reference potential. The multi-layered section has a pixel region and a peripheral region. The first substrate section has a first semiconductor layer provided with a photo-electric converting element and a first wiring layer. The second substrate section has a second semiconductor layer, a second wiring layer, and a third wiring layer. Each of the through via units has a through via penetrating the second semiconductor layer. Each of the dummy via units has a dummy via at least partially buried in the second semiconductor layer. The dummy vias are arranged in the pixel region and in the peripheral region.

### TECHNICAL FIELD

The present disclosure relates to a light detecting device and a multi-layered substrate.

### BACKGROUND ART

Conventionally, technologies in which multiple semiconductor substrates are stacked and bonded to each other for reducing the scale and area of circuits per semiconductor substrate have been used for solid-state imaging devices. For example, a solid-state imaging device in which copper electrode pads are exposed on a bonding surface of each of a pair of semiconductor substrates and electrical connection is also established by bonding the electrode pads to each other has been proposed (e.g., see PTL 1). In this solid-state imaging device, it is attempted to enhance the bonding strength between semiconductor substrates by also bonding dummy pads not used for electrical connection with each other, in addition to the electrode pads used for electrical connection.

However, a solid-state imaging device in which multiple semiconductor substrates are stacked and bonded to each other has a problem that differences in dark current are generated between pixel circuits positioned on electrode pads and pixel circuits positioned on dummy pads, noise occurs to image data due to the differences, and the image quality is degraded (e.g., see PTL 2). One cause of the differences in dark current is supposed to be differences between the amounts of hydrogen supply to the pixel circuits on electrode pads and the amounts of hydrogen supply to the pixel circuits on dummy pads.

In the technology disclosed in PTL 2, vias are connected not only to electrode pads under pixel circuits but also to dummy pads under pixel circuits in order to reduce the differences in dark current described above. With this configuration, it is attempted to supply hydrogen uniformly through the vias to the pixel circuits on electrode pads and the pixel circuits on dummy pads.

### CITATION LIST

### Patent Literature

### [PTL 1]

Japanese Patent Laid-Open No. 2012-164870

### [PTL 2]

Japanese Patent Laid-Open No. 2020-145427

### SUMMARY

### Technical Problem

As multiple semiconductor substrates (e.g., logic boards) having signal processing circuits are stacked, the amount of atoms (e.g., hydrogen (H) atoms) that terminate dangling bonds occluded in the logic boards tends to increase. In conventional technologies, in addition to an increase in dark current, there is a possibility that occluded H atoms move between logic boards and degradation of characteristics such as shifting of the threshold voltage (Vth) of a field-effect transistor, for example, occurs in a logic board which is a destination of supply of H atoms.

The present disclosure has been made in view of such a circumstance, and an object thereof is to provide a light detecting device and a multi-layered substrate that can prevent degradation of characteristics.

### Solution to Problem

A light detecting device according to one aspect of the present disclosure includes a multi-layered section having a first substrate section, a second substrate section provided on a side of one surface of the first substrate section, and a third substrate section provided on the side of the one surface of the first substrate section with the second substrate section interposed therebetween, multiple through via units that are provided in the multi-layered section and electrically connect a first circuit provided at the second substrate section and a second circuit provided at the third substrate section to each other, and multiple dummy via units that are provided in the multi-layered section, are insulated from both the first circuit and the second circuit, and are electrically fixed at a floating or reference potential. The multi-layered section has a pixel region and a peripheral region positioned at a periphery of the pixel region when seen in a plan view as seen in a thickness direction of the multi-layered section. The first substrate section has a first semiconductor layer that has a first surface and a second surface positioned on a side opposite to the first surface and is provided with a photo-electric converting element, and a first wiring layer provided on a side of the first surface of the first semiconductor layer. The second substrate section has a second semiconductor layer having a third surface facing the first semiconductor layer and a fourth surface positioned on a side opposite to the third surface, a second wiring layer provided on a side of the third surface of the second semiconductor layer, and a third wiring layer provided on a side of the fourth surface of the second semiconductor layer. Each of the through via units has a through via penetrating from the third surface to the fourth surface of the second semiconductor layer. Each of the dummy via units has a dummy via at least partially buried in the second semiconductor layer. The dummy vias are arranged in the pixel region and in the peripheral region.

According to this, it is possible to cause atoms (e.g., hydrogen (H) atoms) that terminate dangling bonds to move between the second substrate section and the third substrate section through the through via units and the dummy via units not only in the pixel region, but also in the peripheral region. The movement, between the second substrate section and the third substrate section, of atoms (e.g., H atoms) that terminate dangling bonds can be made uniform, and this can contribute to elimination of uneven distribution of atoms (e.g., H atoms) that terminate dangling bonds.

As a result, in a field-effect transistor included in the second circuit and a field-effect transistor included in a third circuit, the threshold voltage (Vth) shift caused by the presence of atoms (e.g., H atoms) that terminate dangling bonds can be made uniform. Even in a case where the number of stacked layers of substrate sections included in the light detecting device is increased to three or more, degradation of characteristics of the light detecting device can be prevented.

A multi-layered substrate according to one aspect of the present disclosure includes a multi-layered section having a first substrate section, a second substrate section provided on a side of one surface of the first substrate section, and a third substrate section provided on the side of the one surface of the first substrate section with the second substrate section interposed therebetween, multiple through via units that are provided in the multi-layered section and electrically connect a first circuit provided at the second substrate section and a second circuit provided at the third substrate section to each other, and multiple dummy via units that are provided in the multi-layered section, are insulated from both the first circuit and the second circuit, and are electrically fixed at a floating or reference potential. The multi-layered section has a pixel region, a peripheral region positioned at a periphery of the pixel region when seen in a plan view as seen in a thickness direction of the multi-layered section, and a scribe region positioned outside the pixel region with the peripheral region interposed therebetween. The first substrate section has a first semiconductor layer that has a first surface and a second surface positioned on a side opposite to the first surface and is provided with a photo-electric converting element, and a first wiring layer provided on a side of the first surface of the first semiconductor layer. The second substrate section has a second semiconductor layer having a third surface facing the first semiconductor layer and a fourth surface positioned on a side opposite to the third surface, a second wiring layer provided on a side of the third surface of the second semiconductor layer, and a third wiring layer provided on a side of the fourth surface of the second semiconductor layer. Each of the through via units has a through via penetrating from the third surface to the fourth surface of the second semiconductor layer. Each of the dummy via units has a dummy via at least partially buried in the second semiconductor layer. The dummy vias are arranged in the pixel region and in the peripheral region.

According to this, it is possible to cause atoms (e.g., H atoms) that terminate dangling bonds to move between the second substrate section and the third substrate section through the through via units and the dummy via units not only in the pixel region, but also in the peripheral region. The movement, between the second substrate section and the third substrate section, of atoms (e.g., H atoms) that terminate dangling bonds can be made uniform, and this can contribute to elimination of uneven distribution of atoms (e.g., H atoms) that terminate dangling bonds.

As a result, in a field-effect transistor included in the second circuit and a field-effect transistor included in a third circuit, the threshold voltage (Vth) shift caused by the presence of atoms (e.g., H atoms) that terminate dangling bonds can be made uniform. Even in a case where the number of stacked layers of substrate sections included in the multi-layered substrate in which a light detecting device is formed in a panelized manner is increased to three or more, degradation of characteristics of the light detecting device can be prevented.

### BRIEF DESCRIPTION OF DRAWINGS

FIG. 1 is a chip layout diagram illustrating a configuration example of a light detecting device according to a first embodiment of the present disclosure.

FIG. 2 is a block diagram illustrating a configuration example of the light detecting device according to the first embodiment of the present disclosure.

FIG. 3 is an equivalent circuit diagram illustrating a configuration example of a pixel of the light detecting device according to the first embodiment of the present disclosure.

FIG. 4 is a cross-sectional view illustrating a configuration example of the light detecting device according to the first embodiment of the present disclosure.

FIG. 5 is a plan view illustrating a configuration example of a multi-layered substrate according to the first embodiment of the present disclosure.

FIG. 6 is a cross-sectional view illustrating a configuration example of the multi-layered substrate according to the first embodiment of the present disclosure.

FIG. 7 is a plan view illustrating an arrangement example of through vias and dummy through vias in the multi-layered substrate according to the first embodiment of the present disclosure.

FIG. 8 is a cross-sectional view illustrating a configuration example of the multi-layered substrate that is illustrated in FIG. 6 and that has been subjected to dicing.

FIG. 9 is a cross-sectional view illustrating a configuration example of a multi-layered substrate according to a second embodiment of the present disclosure.

FIG. 10 is a plan view illustrating an arrangement example of the through vias and dummy non-through vias in the multi-layered substrate according to the second embodiment of the present disclosure.

FIG. 11 is a cross-sectional view illustrating a configuration example of the multi-layered substrate that is illustrated in FIG. 9 and that has been subjected to dicing.

FIG. 12 is a cross-sectional view illustrating a configuration of a multi-layered substrate according to a modification example of the second embodiment of the present disclosure.

FIG. 13 is a cross-sectional view illustrating a configuration example of a multi-layered substrate according to a third embodiment of the present disclosure.

FIG. 14 is a plan view illustrating an arrangement example of the through vias and the dummy through vias in the multi-layered substrate according to the third embodiment of the present disclosure.

FIG. 15 is a cross-sectional view illustrating a configuration of a multi-layered substrate according to a modification example of the third embodiment of the present disclosure.

FIG. 16 is a plan view illustrating an arrangement example of the through vias and the dummy through vias in the multi-layered substrate according to the modification example of the third embodiment of the present disclosure.

FIG. 17 is a cross-sectional view illustrating a configuration example of a multi-layered substrate according to a fourth embodiment of the present disclosure.

FIG. 18 is a plan view illustrating an arrangement example of the through vias and dummy bonding pads in the multi-layered substrate according to the fourth embodiment of the present disclosure.

FIG. 19 is a cross-sectional view illustrating a configuration of a multi-layered substrate according to a modification example of the fourth embodiment of the present disclosure.

FIG. 20 is a plan view illustrating an arrangement example of the through vias, the dummy through vias, and the dummy bonding pads in the multi-layered substrate according to the modification example of the fourth embodiment of the present disclosure.

FIG. 21 is a cross-sectional view illustrating a configuration example of a multi-layered substrate according to a fifth embodiment of the present disclosure.

FIG. 22 is a cross-sectional view illustrating an enlarged view of barrier metal layers of through via units that the multi-layered substrate according to the fifth embodiment of the present disclosure has.

FIG. 23 is a view illustrating an example of a schematic configuration of an endoscopic surgery system to which the technology according to the present disclosure (present technology) can be applied.

FIG. 24 is a block diagram illustrating an example of a functional configuration of a camera head and a CCU illustrated in FIG. 23.

FIG. 25 is a block diagram illustrating an example of a schematic configuration of a vehicle control system as an example of a mobile body control system to which the technology according to the present disclosure can be applied.

FIG. 26 is a diagram illustrating an example of the installation position of an imaging section.

### DESCRIPTION OF EMBODIMENTS

Hereinbelow, embodiments of the present disclosure are explained with reference to the figures. In the descriptions of the figures that are referred to in the following explanation, identical or similar portions are given identical or similar reference signs. It should be noted that the figures are schematic figures and that the relation between thicknesses and plane dimensions, the ratio between the thicknesses of respective layers, and the like are different from actual ones. Accordingly, specific thicknesses and dimensions should be determined by taking the following explanation into consideration. In addition, needless to say, the relation between dimensions and the ratio included in one figure may be different from those in the other figures.

In addition, definitions of directions such as an up-down direction in the following explanation are definitions that are used simply for convenience of explanation, and do not limit the technical idea of the present disclosure. For example, needless to say, if a target is observed after being rotated 90°, the up-down direction described in an explanation of the target is interpreted as meaning a left-right direction, and if the target is observed after being rotated 180°, the up-down direction described in an explanation of the target is interpreted as meaning an inverted direction.

In addition, in some cases in the following explanation, directions are explained using the terms “X-axis direction,” “Y-axis direction,” and “Z-axis direction.” For example, the Z-axis direction is a thickness direction of a multi-layered section 201 described later. The X-axis direction and the Y-axis direction are directions orthogonal to the Z-axis direction. The X-axis direction, the Y-axis direction, and the Z-axis direction are mutually orthogonal.

### First Embodiment

In an example explained in a first embodiment, the present technology is applied to a light detecting device which is a backside illumination CMOS (Complementary Metal Oxide Semiconductor) image sensor.

### Overall Configuration of Light Detecting Device

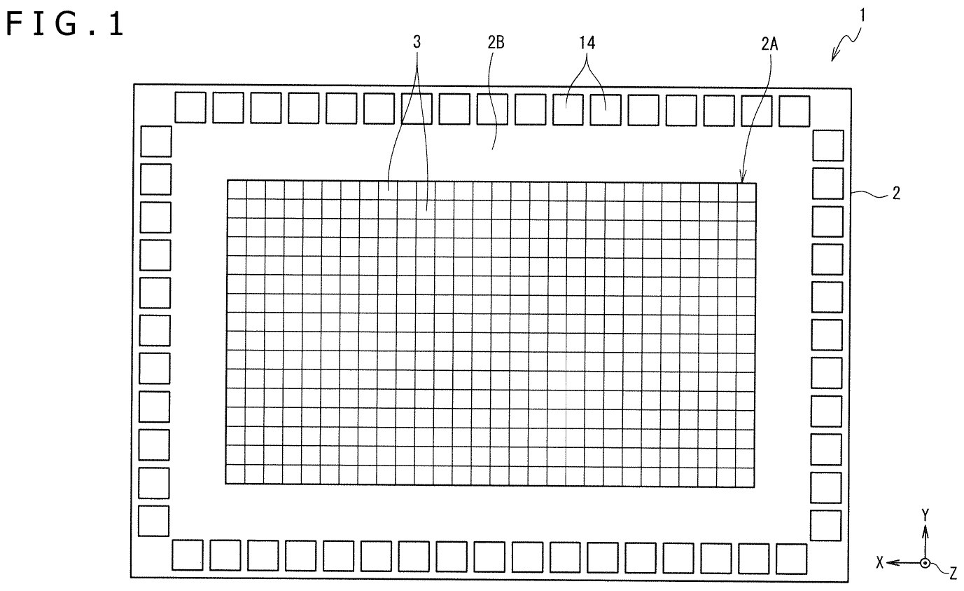

FIG. 1 is a chip layout diagram illustrating a configuration example of a light detecting device 1 according to the first embodiment of the present disclosure. First, an overall configuration of the light detecting device 1 is explained. As illustrated in FIG. 1, the light detecting device 1 according to the first embodiment of the present disclosure mainly includes a semiconductor chip 2 having a two-dimensional plane shape which is quadrangular when seen in a plan view. That is, the light detecting device 1 is mounted on the semiconductor chip 2. The light detecting device 1 takes in image light (incident light) from a subject through an optical lens, converts pixel-by-pixel light amounts of the incident light that has been focused on the imaging surface into electric signals, and outputs the electric signals as pixel signals.

As illustrated in FIG. 1, on a two-dimensional plane including the X-axis direction and the Y-axis direction that intersect each other, the semiconductor chip 2 having the light detecting device 1 mounted thereon includes a quadrangular pixel region 2A (an example of an “element region” of the present disclosure) provided at the middle and a peripheral region 2B provided to surround the pixel region 2A outside the pixel region 2A.

The pixel region 2A is a light reception surface that receives light condensed by an optical system. Further, the pixel region 2A includes multiple pixels 3 that are arranged in a matrix on the two-dimensional plane including the X-axis direction and the Y-axis direction. Stated differently, the pixels 3 are arranged repetitively in each direction of the X-axis direction and the Y-axis direction, which intersect each other on the two-dimensional plane. Note that, as an example, the X-axis direction and the Y-axis direction are orthogonal to each other in the present embodiment. In addition, the direction orthogonal to both the X-axis direction and the Y-axis direction is the Z-axis direction (thickness direction).

As illustrated in FIG. 1, multiple bonding pads 14 are arranged in the peripheral region 2B. Each of the multiple bonding pads 14 is arrayed along each side of the four sides of the semiconductor chip 2 on the two-dimensional plane, for example. Each of the multiple bonding pads 14 is an input/output terminal to be used when the semiconductor chip 2 is electrically connected with an external device.

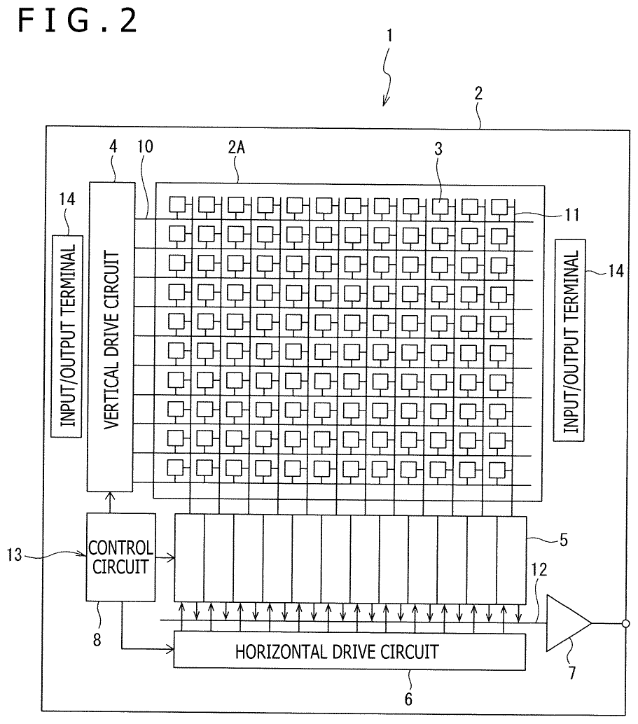

FIG. 2 is a block diagram illustrating a configuration example of the light detecting device 1 according to the first embodiment of the present disclosure. As illustrated in FIG. 2, the semiconductor chip 2 includes a logic circuit 13 including a vertical drive circuit 4, column signal processing circuits 5, a horizontal drive circuit 6, an output circuit 7, a control circuit 8, and the like. The logic circuit 13 includes, as a field-effect transistor, a CMOS (Complementary MOS) circuit having an n-channel-conductivity MOSFET (Metal Oxide Semiconductor Field Effect Transistor) and a p-channel-conductivity MOSFET, for example.

The vertical drive circuit 4 includes a shift register, for example. The vertical drive circuit 4 sequentially selects desired pixel driving lines 10, supplies pulses for driving pixels 3 to each selected pixel driving line 10, and drives pixels 3 row by row. That is, the vertical drive circuit 4 sequentially selects and scans pixels 3 in the pixel region 2A in a vertical direction row by row, and supplies, through vertical signal lines 11 to the column signal processing circuits 5, pixel signals from the pixels 3 based on signal charges generated by photo-electric converting elements of the respective pixels 3 according to received light amounts.

For example, a column signal processing circuit 5 is arranged for each column of pixels 3, and the column signal processing circuits 5 perform signal processing such as noise removal pixel-column by pixel-column on signals output from pixels 3 in one row. For example, the column signal processing circuits 5 perform signal processing such as CDS (Correlated Double Sampling) for removing pixel-specific fixed pattern noise and AD (Analog Digital) conversion. At the output stages of the column signal processing circuits 5, horizontal selection switches (not illustrated) are provided by being connected between the column signal processing circuits 5 and a horizontal signal line 12.

The horizontal drive circuit 6 includes a shift register, for example. By sequentially outputting horizontal scanning pulses to the column signal processing circuits 5, the horizontal drive circuit 6 sequentially selects each of the column signal processing circuits 5, and causes each of the column signal processing circuits 5 to output, to the horizontal signal line 12, a pixel signal on which signal processing has been performed.

The output circuit 7 performs signal processing on pixel signals sequentially supplied from each of the column signal processing circuits 5 through the horizontal signal line 12, and outputs the signals. As the signal processing, for example, buffering, black level adjustment, column variation correction, various types of digital signal processing, and the like can be used.

On the basis of vertical synchronization signals, horizontal synchronization signals, and master clock signals, the control circuit 8 generates reference clock signals and control signals of operation of the vertical drive circuit 4, the column signal processing circuits 5, the horizontal drive circuit 6, and the like. Then, the control circuit 8 outputs the generated clock signals and control signals to the vertical drive circuit 4, the column signal processing circuits 5, the horizontal drive circuit 6, and the like.

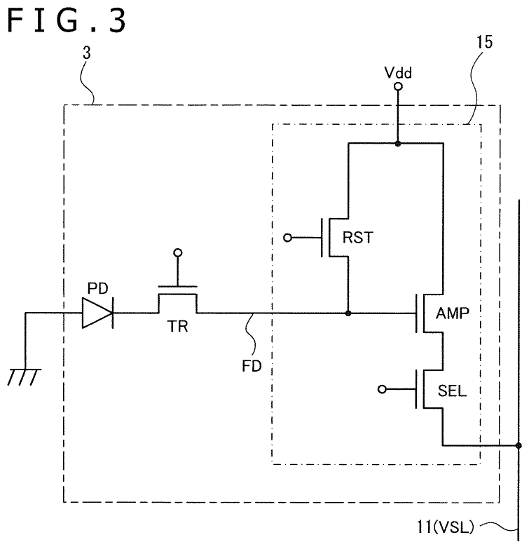

FIG. 3 is an equivalent circuit diagram illustrating a configuration example of a pixel 3 of the light detecting device 1 according to the first embodiment of the present disclosure.

As illustrated in FIG. 3, the pixel 3 includes a photo-electric converting element PD, an electric charge accumulation region (floating diffusion) FD that accumulates (retains) a signal charge photo-electrically converted by the photo-electric converting element PD, and a transfer transistor TR that transfers, to the electric charge accumulation region FD, the signal charge photo-electrically converted by the photo-electric converting element PD. In addition, the pixel 3 includes a readout circuit 15 electrically connected to the electric charge accumulation region FD.

The photo-electric converting element PD generates a signal charge according to a received light amount. In addition, the photo-electric converting element PD temporarily accumulates (retains) the generated signal charge. The photo-electric converting element PD has a cathode side which is electrically connected with a source region of the transfer transistor TR and an anode side which is electrically connected with a reference potential line (e.g., a ground). For example, a photodiode is used as the photo-electric converting element PD.

A drain region of the transfer transistor TR is electrically connected with the electric charge accumulation region FD. A gate electrode of the transfer transistor TR is electrically connected with a transfer transistor drive line in the pixel driving lines 10 (see FIG. 2).

The electric charge accumulation region FD temporarily accumulates and retains a signal charge transferred through the transfer transistor TR from the photo-electric converting element PD.

The readout circuit 15 reads out a signal charge accumulated in the electric charge accumulation region FD, and outputs a pixel signal based on the signal charge. As pixel transistors, the readout circuit 15 includes an amplification transistor AMP, a selection transistor SEL, and a reset transistor RST, for example, although these are not limitative. For example, these transistors (AMP, SEL, and RST) each include a MOSFET having a gate insulating film including a silicon oxide film (SiO2 film), a gate electrode, and a pair of main electrode regions that function as a source region and a drain region. In addition, there are no problems even if these transistors are a MISFET (Metal Insulator Semiconductor FET) including a gate insulating film which is a silicon nitride film (Si3N4 film) or a multi-layered film including a silicon nitride film and a silicon oxide film or the like.

The amplification transistor AMP has a source region which is electrically connected with the drain region of the selection transistor SEL and a drain region which is electrically connected with a power line Vdd and a drain region of the reset transistor. Further, a gate electrode of the amplification transistor AMP is electrically connected with the electric charge accumulation region FD and a source region of the reset transistor RST.

The selection transistor SEL has a source region which is electrically connected with a vertical signal line 11 (VSL) and a drain which is electrically connected with the source region of the amplification transistor AMP. Further, a gate electrode of the selection transistor SEL is electrically connected with a selection transistor drive line in the pixel driving lines 10 (see FIG. 2).

The reset transistor RST has the source region electrically connected with the electric charge accumulation region FD and the gate electrode of the amplification transistor AMP and the drain region electrically connected with the power line Vdd and the drain region of the amplification transistor AMP. A gate electrode of the reset transistor RST is electrically connected with a reset transistor drive line in the pixel driving line 10 (see FIG. 2).

### Specific Configuration of Light Detecting Device

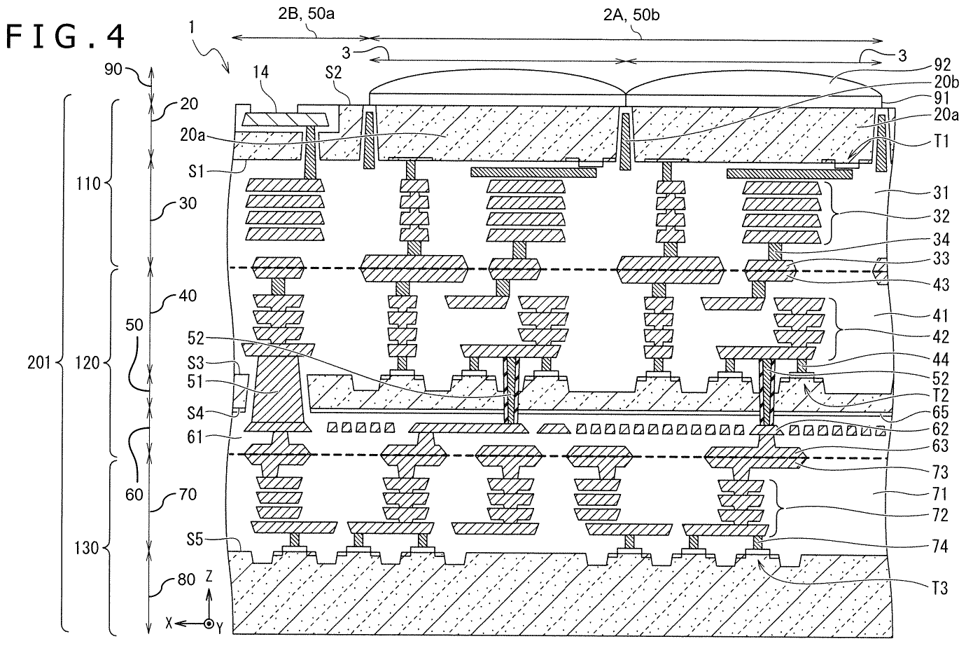

Next, a specific configuration of the light detecting device 1 is explained with reference to FIG. 4.

### (1) Multi-Layered Structure

FIG. 4 is a cross-sectional view illustrating a configuration example of the light detecting device 1 according to the first embodiment of the present disclosure. As illustrated in FIG. 4, the light detecting device 1 (semiconductor chip 2) includes a light-condensing layer 90, a first substrate section 110, a second substrate section 120, and a third substrate section 130. The first substrate section 110, the second substrate section 120, and the third substrate section 130 have a multi-layered structure in which these are stacked in this order from the side of the light-condensing layer 90. This multi-layered structure is also referred to as the multi-layered section 201.

The first substrate section 110 has a first semiconductor layer 20 and a first wiring layer 30 that are stacked in this order from the side of the light-condensing layer 90. The second substrate section 120 includes a second wiring layer 40, a second semiconductor layer 50, and a third wiring layer 60 that are stacked in this order from the side of the light-condensing layer 90. The third substrate section 130 includes a fourth wiring layer 70 and a third semiconductor layer 80 that are stacked in this order from the side of the light-condensing layer 90.

The light-condensing layer 90 has a multi-layered structure in which, for example, color filters 91 and on-chip lenses 92 (examples of an “optical lens” of the present disclosure) are stacked in this order from the side of a back surface S2 of the first semiconductor layer 20, although these are not limitative. The on-chip lenses 92 condense incident light that is incident on the first substrate section 110 onto photo-electric converting elements PD. For example, the on-chip lenses 92 are arranged in the pixel region 2A, but are not arranged in the peripheral region 2B.

In the first substrate section 110, the first semiconductor layer 20 has a photo-electric conversion region described later. One surface of the first semiconductor layer 20 is a main surface S1 (an example of a “first surface” of the present disclosure), and the other surface of the first semiconductor layer 20 is the back surface S2 (an example of a “second surface” of the present disclosure), which is a light incidence surface. The first wiring layer 30 is superimposed on the main surface S1 of the first semiconductor layer 20.

In the second substrate section 120, the second wiring layer 40 is superimposed on a surface of the first wiring layer 30 opposite to a surface on the side of the first semiconductor layer 20. The second semiconductor layer 50 has multiple transistors. One surface of the second semiconductor layer 50 is a main surface S3 (an example of a “third surface” of the present disclosure), and the other surface of the second semiconductor layer 50 is a back surface S4 (an example of a “fourth surface” of the present disclosure). The main surface S3 is superimposed on a surface of the second wiring layer 40 opposite to a surface on the side of the first wiring layer 30. The third wiring layer 60 is superimposed on the back surface S4 of the second semiconductor layer 50.

In the third substrate section 130, the fourth wiring layer 70 is superimposed on a surface of the third wiring layer 60 opposite to a surface on the side of the second semiconductor layer 50. A main surface S5 (an example of a “fifth surface” of the present disclosure) of the third semiconductor layer 80 is superimposed on a surface of the fourth wiring layer 70 opposite to a surface on the side of the third wiring layer 60.

Here, the main surface S1 of the first semiconductor layer 20, the main surface S3 of the second semiconductor layer 50, and the main surface S5 of the third semiconductor layer 80 are each called an element formation surface in some cases.

In addition, the first semiconductor layer 20 and the second semiconductor layer 50 are bonded to each other by the F2F (Face to Face) method, that is, such that the element formation surfaces face each other, with the first wiring layer 30 and the second wiring layer 40 interposed therebetween. Further, the second semiconductor layer 50 and the third semiconductor layer 80 are bonded to each other by the B2F (Back to Face) method, that is, such that the back surface and the element formation surface face each other, with the third wiring layer 60 and the fourth wiring layer 70 interposed therebetween.

### (2) Configuration of Each Section

The first semiconductor layer 20 includes a semiconductor substrate. The first semiconductor layer 20 includes a first-conductivity single crystal silicon substrate, for example, a p-type single crystal silicon substrate. In addition, for example, a region in the first semiconductor layer 20 overlapping the peripheral region 2B in a plan view is provided with the bonding pads 14. Further, a photo-electric conversion region 20a is provided for each pixel 3 in a region in the first semiconductor layer 20 overlapping the pixel region 2A in the plan view. For example, an island-like photo-electric conversion region 20a divided by a separation region 20b is provided for each pixel 3. Note that the number of pixels 3 is not limited to the number of pixels illustrated in FIG. 4.

Although an illustration is omitted, each photo-electric conversion region 20a has a first-conductivity well region, for example, a p-type well region, and a second-conductivity semiconductor region, for example, an n-type semiconductor region (photo-electric converting section) buried inside the well region. The photo-electric converting element PD illustrated in FIG. 3 is configured in each photo-electric conversion region 20a including the well region and the photo-electric converting section on the first semiconductor layer 20. In addition, each photo-electric conversion region 20a may be provided with an unillustrated electric charge accumulation region which is a second-conductivity semiconductor region, for example, an n-type semiconductor region, and a transistor T1, although these are not limitative. For example, the transistor T1 is the transfer transistor TR illustrated in FIG. 3.

For example, the separation region 20b has a trench structure in which separation grooves are formed in the first semiconductor layer 20 and insulating films are embedded in the separation grooves, although this is not limitative. In the example illustrated in FIG. 4, insulating films and metal are embedded in the separation grooves.

The first wiring layer 30 includes an insulating film 31, wires 32, connection pads 33, and vias (contacts) 34. As illustrated in the figure, the wires 32 and the connection pads 33 are stacked one on another with the insulating film 31 interposed therebetween. The connection pads 33 are on a surface of the first wiring layer 30 opposite to the side of the first semiconductor layer 20. The vias 34 connect the first semiconductor layer 20 and the wires 32 to each other, connect the wires 32 to each other, and connect the wires 32 and the connection pads 33 to each other, for example. In addition, the wires 32 and the connection pads 33 include copper (Cu), for example, and may be formed by a damascene method, although this is not limitative.

The second wiring layer 40 includes an insulating film 41, wires 42, connection pads 43, and vias (contacts) 44. As illustrated in the figure, the wires 42 and the connection pads 43 are stacked one on another with the insulating film 41 interposed therebetween. The connection pads 43 are on a surface of the second wiring layer 40 opposite to the side of the second semiconductor layer 50, and are bonded to the connection pads 33. The vias 44 connect the second semiconductor layer 50 and the wires 42 to each other, connect the wires 42 to each other, and connect the wires 42 and the connection pads 43 to each other, for example. In addition, the wires 42 and the connection pads 43 include copper, for example, and may be formed by a damascene method, although this is not limitative. Note that the wires 42 and the vias 44 are examples of a “first wire” of the present disclosure.

The second semiconductor layer 50 includes a semiconductor substrate. The second semiconductor layer 50 includes a single crystal silicon substrate, although this is not limitative. The second semiconductor layer 50 exhibits a first conductivity, for example, a p type. The second semiconductor layer 50 is provided with multiple transistors T2. More specifically, the transistors T2 are provided in a region of the second semiconductor layer 50 overlapping the pixel region 2A in the plan view. For example, each transistor T2 is a transistor included in the readout circuit 15 illustrated in FIG. 3.

Note that at least some circuits which are included in the logic circuit 13 illustrated in FIG. 2 and the readout circuit 15 illustrated in FIG. 3 and which are provided on the second semiconductor layer 50 are examples of the “first circuit” of the present disclosure. The “first circuit” of the present disclosure may be a logic circuit, may be an analog circuit, or may be a circuit on which a logic circuit and an analog circuit are mixedly mounted.

Note that, in order to make a distinction between a region overlapping the pixel region 2A in the plan view and a region overlapping the peripheral region 2B in the plan view in the second semiconductor layer 50, the region overlapping the peripheral region 2B is called a first region 50a, and the region overlapping the pixel region 2A is called a second region 50b.

The second semiconductor layer 50 is provided with first conductors 51 and second conductors 52. More specifically, the first region 50a is provided with the first conductors 51 that have a first width, include a first material, and penetrate the second semiconductor layer 50 along the thickness direction. Further, the second region 50b is provided with the second conductors 52 that have a second width smaller than the first width, include a second material different from the first material, and penetrate the second semiconductor layer 50 along the thickness direction. The first conductors 51 and the second conductors 52 are conductors (electrodes) penetrating the semiconductor layer. Since the semiconductor layer includes silicon in the present embodiment, for example, the first conductors 51 and the second conductors 52 are through-silicon vias (TSVs).

The first conductors 51 are used as power lines, for example, although this is not limitative. Accordingly, the first conductors 51 are preferably of electrically low-resistance. In view of this, as the first material included in the first conductors 51, a conductive material with a low electrical resistivity is preferably used. Here, as the first material, copper, which is an example of such a conductive material, is used. In addition, the resistance of the first conductors 51 can be reduced by increasing the first width. Since the first region 50a provided with the first conductors 51 has a low density of arrangement of elements and wires, the first width can be increased.

Since the second conductors 52 are provided in the second region 50b provided with the multiple transistors T2, the second conductors 52 have to be provided in small regions between the transistors T2 in some cases. Accordingly, the second width needs to be reduced. If the second width is reduced, the aspect ratio of the second conductors 52 increases. The aspect ratio of the second conductors 52 becomes equal to or greater than 5, for example, in some cases, although this is not limitative. It is difficult with such an aspect ratio to embed the same material as the first material (here, copper, for example), in some cases. In view of this, as the second material included in the second conductor 52, a conductive material with favorable embeddability relative to holes with a high aspect ratio may be used. Examples of such a conductive material include high-melting point metals. For example, examples of high-melting point metals include tungsten (W), cobalt (Co), ruthenium (Ru), and metal materials including at least one of them. For example, tungsten may be used as the second material.

As illustrated in FIG. 4, the third wiring layer 60 includes an insulating film 61, wires 62 (examples of a “second wire” of the present disclosure), connection pads 63 (examples of a “first connection pad” of the present disclosure), and a silicon cover film 65. As illustrated in the figure, the wires 62 and the connection pads 63 are stacked one on another with the insulating film 61 interposed therebetween. The connection pads 63 are on a surface of the third wiring layer 60 opposite to the side of the second semiconductor layer 50. The wires 62 and the connection pads 63 include copper, for example, and may be formed by a damascene method, although this is not limitative.

The silicon cover film 65 is provided in order to prevent light emitted from elements from being reflected, and includes a high-melting-point oxide.

As illustrated in FIG. 4, the fourth wiring layer 70 includes an insulating film 71, wires 72, connection pads 73 (examples of a “second connection pad” of the present disclosure), and vias (contacts) 74. As illustrated in the figure, the wires 72 and the connection pads 73 are stacked one on another with the insulating film 71 interposed therebetween. The connection pads 73 are on a surface of the fourth wiring layer 70 opposite to the side of the third semiconductor layer 80, and are bonded to the connection pads 63. The vias 74 connect the third semiconductor layer 80 and the wires 72 to each other, connect the wires 72 to each other, and connect the wires 72 and the connection pads 73 to each other, for example. In addition, the wires 72 and the connection pads 73 include copper, for example, and may be formed by a damascene method, although this is not limitative. Note that the wires 72 and the vias 74 are examples of a “third wire” of the present disclosure.

The third semiconductor layer 80 includes a semiconductor substrate. The third semiconductor layer 80 includes a first-conductivity single crystal silicon substrate, for example, a p-type single crystal silicon substrate. The third semiconductor layer 80 is provided with multiple transistors T3. More specifically, the transistors T3 are provided in a region of the third semiconductor layer 80 overlapping the pixel region 2A and the peripheral region 2B in the plan view. For example, each transistor T3 is a transistor included in the logic circuit 13 illustrated in FIG. 2.

Note that at least some circuits which are included in the logic circuit 13 illustrated in FIG. 2 and the readout circuit 15 illustrated in FIG. 3 and which are provided on the third semiconductor layer 80 are examples of a “second circuit” of the present disclosure. The “second circuit” of the present disclosure may be a logic circuit, may be an analog circuit, or may be a circuit on which a logic circuit and an analog circuit are mixedly mounted.

The light detecting device 1 illustrated in FIG. 4 is manufactured by dicing a multi-layered substrate having the multi-layered section 201 in which the first substrate section 110, the second substrate section 120, and the third substrate section 130 are stacked one on another.

### (3) Chip Region and Scribe Region

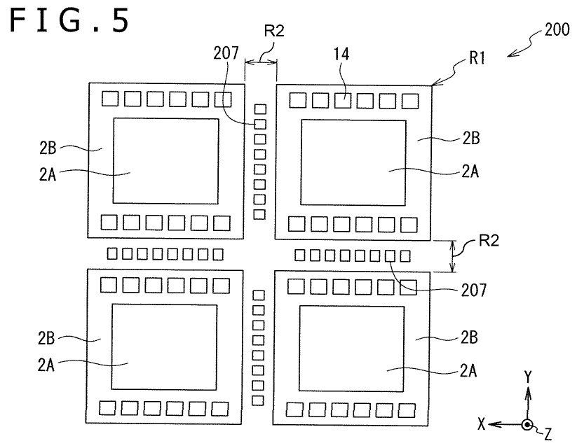

FIG. 5 is a plan view illustrating a configuration example of a multi-layered substrate 200 according to the first embodiment of the present disclosure. For example, the multi-layered substrate 200 illustrated in FIG. 5 is a wafer having the multi-layered section 201 in which the first substrate section 110, the second substrate section 120, and the third substrate section 130 illustrated in FIG. 4 are stacked one on another.

The multi-layered substrate 200 is provided with multiple chip regions R1. Each of the multiple chip regions R1 includes a pixel region 2A and a peripheral region 2B positioned at the periphery of the pixel region 2A. The multiple chip regions R1 are arranged next to each other in each of the X-axis direction and the Y-axis direction orthogonal to the X-axis direction when seen in a plan view as seen in the thickness direction of the multi-layered substrate 200 (i.e., the thickness direction of the multi-layered section 201 having the first substrate section 110, the second substrate section 120, and the third substrate section 130; for example, the Z-axis direction).

A scribe region R2 is provided between one chip region R1 and another chip region R1 that are adjacent to each other in the multiple chip regions R1. The scribe region R2 is provided to extend in both the X-axis direction and the Y-axis direction. By cutting the scribe region R2, the multiple chip regions R1 are diced into semiconductor chips 2.

### (4) Configuration Examples of Through Via Units and Dummy Through Via Units

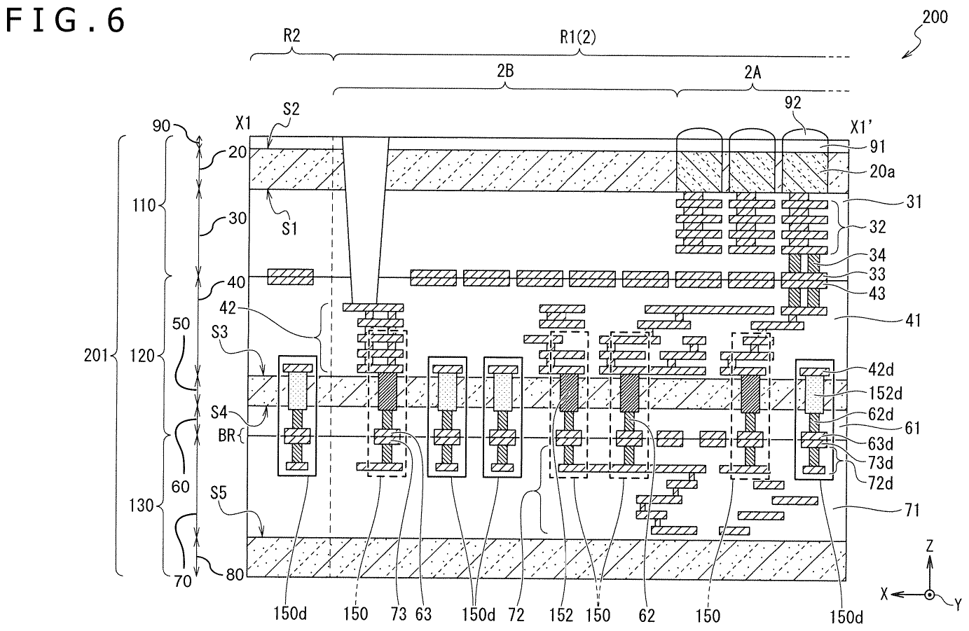

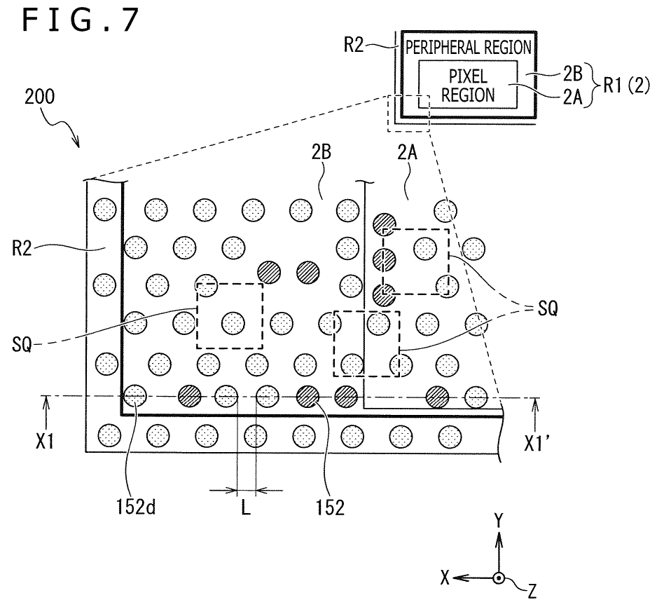

FIG. 6 is a cross-sectional view illustrating a configuration example of the multi-layered substrate 200 according to the first embodiment of the present disclosure. FIG. 7 is a plan view illustrating an arrangement example of through vias 152 and dummy through vias 152d in the multi-layered substrate 200 according to the first embodiment of the present disclosure. Note that a cross-section taken along a line X1-X1′ in the plan view in FIG. 7 corresponds to the cross-sectional view in FIG. 6.

As illustrated in FIG. 6 and FIG. 7, the multi-layered substrate 200 includes multiple through via units 150 that are provided in the multi-layered section 201 and electrically connect first circuits provided at the second substrate section 120 and second circuits provided at the third substrate section 130 and multiple dummy through via units 150d (an example of “dummy via units” of the present disclosure) that are provided in the multi-layered section 201, are insulated from both the first circuits and the second circuits, and are electrically fixed at a floating or reference potential (e.g., a ground potential (0 V)).

As described above, for example, the first circuits are at least some circuits which are included in the logic circuit 13 illustrated in FIG. 2 and the readout circuit 15 illustrated in FIG. 3 and which are provided on the second semiconductor layer 50. For example, the second circuits are at least some circuits which are included in the logic circuit 13 illustrated in FIG. 2 and the readout circuit 15 illustrated in FIG. 3 and which are provided on the third semiconductor layer 80.

Each through via unit 150 has a through via 152 penetrating from the main surface S3 to the back surface S4 of the second semiconductor layer 50, a wire 42 that is provided in the second wiring layer 40 and is connected to one end of the through via 152, a wire 62 that is provided in the third wiring layer 60 and is connected to the other end of the through via 152, a wire 72 provided in the fourth wiring layer 70, and a connection pad provided at a boundary section BR between the third wiring layer 60 and the fourth wiring layer 70.

The through vias 152 are conductors (electrodes) penetrating the second semiconductor layer 50. Since the second semiconductor layer 50 includes silicon, for example, the through vias 152 are through-silicon vias (TSVs). The through vias 152 are formed being embedded in through-holes penetrating the second semiconductor layer 50, with insulating films (not illustrated) interposed therebetween.

For example, the through vias 152 have the same shape and structure as those of the second conductors 52 (see FIG. 4). The through vias 152 include the same material as that of the second conductors 52, for example, copper (Cu) or a Cu alloy, or aluminum (Al) or an Al alloy.

Alternatively, the material included in the through vias 152 may be a conductive material with favorable embeddability relative to holes with a high aspect ratio. Examples of such a conductive material include high-melting point metals. For example, examples of high-melting point metals include tungsten (W), cobalt (Co), ruthenium (Ru), and metal materials including at least one of them. For example, the material included in the through vias 152 may be tungsten.

Alternatively, at least some of the through vias 152 may have the same shape and structure as those of the first conductors 51 (see FIG. 4), for example. In this case, the through vias 152 may include the same material (e.g., Cu) as that of the first conductors 51.

For example, the wires 42, 62, and 72 include copper (Cu) or a Cu alloy. Alternatively, the wires 42, 62, and 72 may include aluminum (Al) or an Al alloy. For example, the connection pads 63 and 73 include Cu or a Cu alloy.

Note that, whereas the wires 62 include only vias (contacts) in the case illustrated in the example illustrated in FIG. 6, this is merely an example. Similarly to the wires 42 and 72, the wires 62 may be multi-layered wires stacked in multi-layered structures with vias (contacts) interposed therebetween. In addition, whereas the wires 42 and 72 are multi-layered wires in the case illustrated in the example illustrated in FIG. 6, this is merely an example. The wires 42 and 72 may include only vias (contacts).

The connection pads connect the wires 62 and the wires 72 to each other, and also bond the second substrate section 120 and the third substrate section 130 to each other. For example, the connection pads have the connection pads 63 provided on the side of the third wiring layer 60 relative to the boundary section BR and the connection pads 73 provided on the side of the fourth wiring layer 70 relative to the boundary section BR.

Each dummy through via unit 150d has a dummy through via 152d (an example of “dummy vias” and “dummy through vias” of the present disclosure) penetrating from the main surface S3 to the back surface S4 of the second semiconductor layer 50, a dummy wire 42d (an example of a “first dummy wire” of the present disclosure) that is provided in the second wiring layer 40 and is connected to one end of the dummy through via 152d, a dummy wire 62d (an example of a “second dummy wire” of the present disclosure) that is provided in the third wiring layer 60 and is connected to the other end of the dummy through via 152d, a dummy wire 72d (an example of a “third dummy wire” of the present disclosure) provided in the fourth wiring layer 70, and a dummy connection pad provided at the boundary section BR between the third wiring layer 60 and the fourth wiring layer 70.

The dummy through vias 152d are conductors (electrodes) penetrating the second semiconductor layer 50. Since the second semiconductor layer 50 includes silicon, for example, the dummy through vias 152d are through-silicon vias (TSVs). The dummy through vias 152d are formed being embedded in through-holes penetrating the second semiconductor layer 50, with insulating films (not illustrated) interposed therebetween.

For example, the dummy through vias 152d include the same material as that of the through vias 152 of the through via units 150, and have the same structure as that of the through vias 152. For example, the material included in the dummy through vias 152d is copper (Cu) or a Cu alloy, or aluminum (Al) or an Al alloy.

Alternatively, the dummy through vias 152d may include a conductive material with favorable embeddability relative to holes with a high aspect ratio. Examples of such a conductive material include high-melting point metals. For example, examples of high-melting point metals include tungsten (W), cobalt (Co), ruthenium (Ru), and metal materials including at least one of them. For example, the material included in the dummy through vias 152d may be tungsten.

For example, the dummy wires 42d, 62d, and 72d include copper (Cu) or a Cu alloy. Alternatively, the dummy wires 42d, 62d, and 72d may include aluminum (Al) or an Al alloy. For example, dummy connection pads 63d and 73d include Cu or a Cu alloy.

Note that, whereas the dummy wires 62d include only vias (contacts) in the case illustrated in the example illustrated in FIG. 6, this is merely an example. Similarly to the dummy wires 42d and 72d, the dummy wires 62d may be multi-layered dummy wires stacked in multi-layered structures with vias (contacts) interposed therebetween or may be single-layered dummy wires. In addition, whereas the dummy wires 42d and 72d are multi-layered dummy wires or single-layered dummy wires in the case illustrated in the example illustrated in FIG. 6, this is merely an example. The dummy wires 42d and 72d may include only vias (contacts).

The dummy connection pads connect the dummy wires 62d and the dummy wires 72d to each other, and also bond the second substrate section 120 and the third substrate section 130 to each other. For example, the dummy connection pads have the dummy connection pads 63d (examples of a “first dummy connection pad” of the present disclosure) provided on the side of the third wiring layer 60 relative to the boundary section BR and the dummy connection pads 73d (examples of a “second dummy connection pad” of the present disclosure) provided on the side of the fourth wiring layer 70 relative to the boundary section BR. Cu which is the constituent materials of the dummy connection pads 63d and Cu which is the constituent materials of the dummy connection pads 73d are bonded directly to each other (i.e., the dummy connection pads 63d and 73d are bonded to each other by Cu-Cu bonding).

### (5) Arrangement Examples of Through Via Units and Dummy Through Via Units

As illustrated in FIG. 7, the through via units 150 and the dummy through via units 150d are arranged in the pixel region 2A and in the peripheral region 2B. In addition, the dummy through via units 150d are arranged also in the scribe region R2 positioned outside the pixel region 2A (i.e., positioned outside the chip region R1) with the peripheral region 2B interposed therebetween. The dummy through via units 150d are arranged in a blank region where the through via units 150 are not arranged (or where the through via units 150 are arranged scarcely).

The area density of the dummy through vias 152d when seen in the plan view as seen in the thickness direction of the multi-layered section 201 (e.g., the Z-axis direction) is preferably equal to or higher than 0.1%, and is more preferably equal to or higher than 1%, in a rectangular region SQ of 100 μm in length×100 μm in width which is located at any position in the chip region R1 (i.e., in a region that includes at least one of the pixel region 2A and the peripheral region 2B).

In addition, when seen in the plan view as seen in the thickness direction of the multi-layered section 201 (e.g., the Z-axis direction), a distance L between one dummy through via 152d and another dummy through via 152d that is adjacent to the one dummy through via 152d at the shortest distance is preferably equal to or shorter than 100 μm, and is more preferably equal to or shorter than 20 μm.

With this configuration, it becomes easier to cause atoms (e.g., H atoms) that terminate dangling bonds to move between the second substrate section 120 and the third substrate section 130 through the dummy through via units 150d. It becomes easier to make uniform the movement of atoms (e.g., H atoms) that terminate dangling bonds, between the second substrate section 120 and the third substrate section 130.

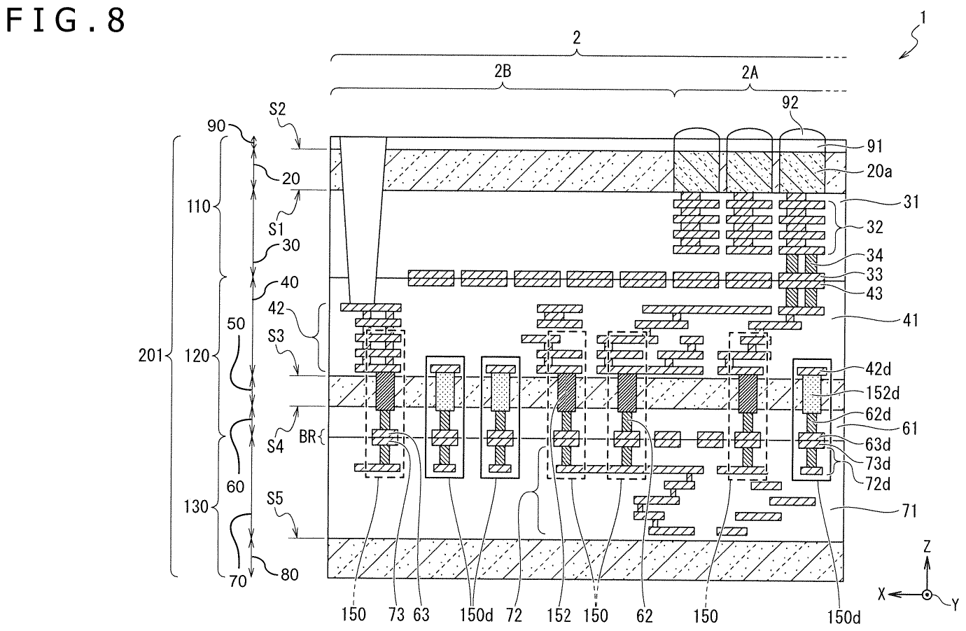

FIG. 8 is a cross-sectional view illustrating a configuration example of the multi-layered substrate 200 that is illustrated in FIG. 6 and that has been subjected to dicing. By dicing the multi-layered substrate 200 illustrated in FIG. 6 (i.e., by cutting the scribe region R2), the multi-layered substrate 200 is diced into the multiple chip regions R1. As a result, the semiconductor chip 2 on which the light detecting device 1 is mounted can be obtained as illustrated in FIG. 8.

### Advantages of First Embodiment

As explained above, the light detecting device according to the first embodiment of the present disclosure includes the multi-layered section 201 having the first substrate section 110, the second substrate section 120 provided on the side of one surface of the first substrate section 110, and the third substrate section 130 provided on the side of the one surface of the first substrate section 110 with the second substrate section 120 interposed therebetween, the multiple through via units 150 that are provided in the multi-layered section 201 and electrically connect the first circuits provided at the second substrate section 120 and the second circuits provided at the third substrate section 130 to each other, and the multiple dummy through via units 150d that are provided in the multi-layered section 201, are insulated from both the first circuits and the second circuits, and are electrically fixed at a floating or reference potential.

The multi-layered section 201 has the pixel region 2A and the peripheral region 2B positioned at the periphery of the pixel region 2A when seen in a plan view as seen in the thickness direction of the multi-layered section 201. The first substrate section 110 has the first semiconductor layer 20 that has the main surface S1 and the back surface S2 positioned on a side opposite to the main surface S1 and that is provided with the photo-electric converting elements PD and the first wiring layer 30 provided on the side of the main surface S1 of the first semiconductor layer 20. The second substrate section 120 has the second semiconductor layer 50 having the main surface S3 facing the first semiconductor layer 20 and the back surface S4 positioned on a side opposite to the main surface S3, the second wiring layer 40 provided on the side of the main surface S3 of the second semiconductor layer 50, and the third wiring layer 60 provided on the side of the back surface S4 of the second semiconductor layer 50.

The through via units 150 have the through vias 152 penetrating from the main surface S3 to the back surface S4 of the second semiconductor layer 50. The dummy through via units 150d have the dummy through vias 152d at least partially buried in the second semiconductor layer 50. The dummy through vias 152d are arranged in the pixel region 2A and in the peripheral region 2B.

According to this, it is possible to cause atoms (e.g., hydrogen (H) atoms) that terminate dangling bonds to move between the second substrate section 120 and the third substrate section 130 through the through via units 150 and the dummy through via units 150d not only in the pixel region 2A, but also in the peripheral region 2B. The movement, between the second substrate section 120 and the third substrate section 130, of atoms (e.g., H atoms) that terminate dangling bonds can be made uniform, and this can contribute to elimination of uneven distribution of atoms (e.g., H atoms) that terminate dangling bonds.

As a result, in field-effect transistors included in the second circuits and field-effect transistors included in third circuits, the threshold voltage (Vth) shift caused by the presence of atoms (e.g., H atoms) that terminate dangling bonds can be made uniform. Even in a case where the number of stacked layers of substrate sections is increased to three or more, degradation of characteristics of the light detecting device can be prevented.

In the multi-layered substrate 200 according to the first embodiment of the present disclosure, the multi-layered section 201 has the pixel region 2A, the peripheral region 2B positioned at the periphery of the pixel region 2A when seen in the plan view as seen in the thickness direction of the multi-layered section 201, and the scribe region R2 positioned outside the pixel region 2A with the peripheral region 2B interposed therebetween. The dummy through vias 152d that the dummy through via units 150d have are arranged in the pixel region 2A and in the peripheral region 2B. The dummy through vias 152d may further be arranged in the scribe region R2.

According to this, it is possible to cause atoms (e.g., H atoms) that terminate dangling bonds to move between the second substrate section 120 and the third substrate section 130 through the through via units 150 and the dummy through via units 150d not only in the pixel region 2A, but also in the peripheral region 2B and the scribe region R2. The movement, between the second substrate section 120 and the third substrate section 130, of atoms (e.g., H atoms) that terminate dangling bonds can be made uniform, and this can contribute to elimination of uneven distribution of atoms (e.g., H atoms) that terminate dangling bonds.

As a result, in field-effect transistors included in the second circuits and field-effect transistors included in the third circuits, the threshold voltage (Vth) shift caused by the presence of atoms (e.g., H atoms) that terminate dangling bonds can be made uniform. Even in a case where the number of stacked layers of substrate sections is increased to three or more in the multi-layered substrate 200 in which the light detecting device 1 is formed in a panelized manner, degradation of characteristics of the light detecting device 1 can be prevented.

### Second Embodiment

In the first embodiment described above, the dummy through vias 152d penetrating the second semiconductor layer 50 are illustrated as examples of the “dummy vias” of the present disclosure. However, the “dummy vias” of the present disclosure may be non-through dummy vias not penetrating the second semiconductor layer 50.

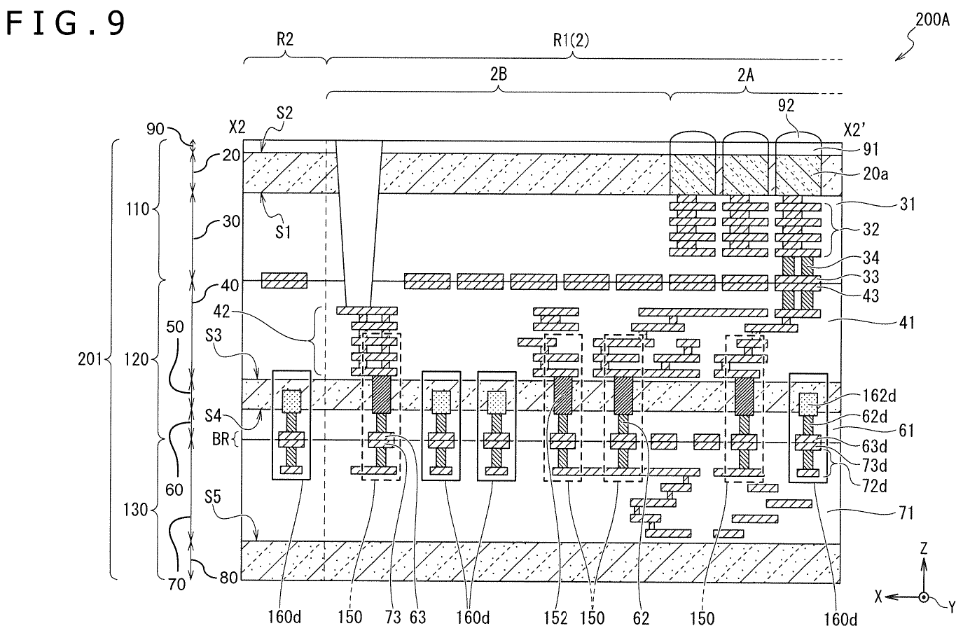

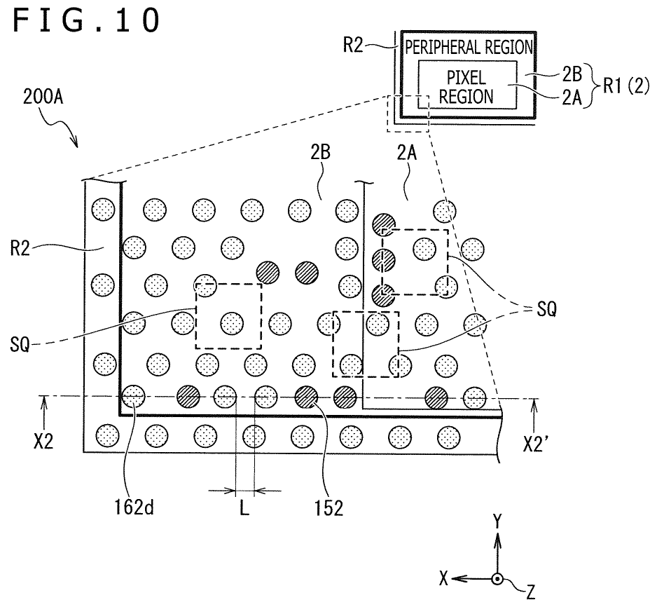

FIG. 9 is a cross-sectional view illustrating a configuration example of a multi-layered substrate 200A according to a second embodiment of the present disclosure. FIG. 10 is a plan view illustrating an arrangement example of the through vias 152 and dummy non-through vias 162d in the multi-layered substrate 200A according to the second embodiment of the present disclosure. Note that a cross-section taken along a line X2-X2′ in the plan view in FIG. 10 corresponds to the cross-sectional view in FIG. 9.

As illustrated in FIG. 9 and FIG. 10, the multi-layered substrate 200A includes multiple through via units 150 that are provided in the multi-layered section 201 and electrically connect first circuits provided at the second substrate section 120 and second circuits provided at the third substrate section 130 to each other and multiple dummy non-through via units 160d (an example of the “dummy via units” of the present disclosure) that are provided in the multi-layered section 201, are insulated from both the first circuits and the second circuits, and are electrically fixed at a floating or reference potential (e.g., a ground potential (0 V)).

Each dummy non-through via unit 160d has a dummy non-through via 162d (an example of the “dummy vias” of the present disclosure) embedded in the second semiconductor layer 50 from the side of the back surface S4 of the second semiconductor layer 50, a dummy wire 62d that is provided in the third wiring layer 60 and is connected to the dummy non-through via 162d, a dummy wire 72d provided in the fourth wiring layer 70, and a dummy connection pad provided at the boundary section BR between the third wiring layer 60 and the fourth wiring layer 70.

Also in the multi-layered substrate 200A, the dummy connection pads connect the dummy wires 62d and the dummy wires 72d to each other, and also bond the second substrate section 120 and the third substrate section 130 to each other. For example, the dummy connection pads have the dummy connection pads 63d provided on the side of the third wiring layer 60 relative to the boundary section BR and the dummy connection pads 73d provided on the side of the fourth wiring layer 70 relative to the boundary section BR. The dummy connection pads 63d and 73d are bonded to each other by Cu-Cu bonding.

The dummy non-through vias 162d are non-through conductors (electrodes) embedded in the second semiconductor layer 50. The dummy non-through vias 162d do not penetrate the second semiconductor layer 50. The dummy non-through vias 162d are formed being embedded in openings that are formed on the back surface S4 of the second semiconductor layer 50, with insulating films (not illustrated) interposed therebetween.

For example, the dummy non-through vias 162d include the same material as that of the through vias 152 of the through via units 150, and have the same structure as that of the through vias 152. For example, the material included in the dummy non-through vias 162d is copper (Cu) or a Cu alloy, or aluminum (Al) or an Al alloy.

Alternatively, the dummy non-through vias 162d may include a conductive material with favorable embeddability relative to holes with a high aspect ratio. Examples of such a conductive material include high-melting point metals. For example, examples of high-melting point metals include tungsten (W), cobalt (Co), ruthenium (Ru), and metal materials including at least one of them. For example, the material included in the dummy non-through vias 162d may be tungsten.

As illustrated in FIG. 10, the through via units 150 and the dummy non-through via units 160d are arranged in the pixel region 2A and in the peripheral region 2B. In addition, the dummy non-through via units 160d are arranged also in the scribe region R2 positioned outside the pixel region 2A (i.e., positioned outside the chip region R1) with the peripheral region 2B interposed therebetween. The dummy non-through via units 160d are arranged in a blank region where the through via units 150 are not arranged (or where the through via units 150 are arranged scarcely).

The area density of the dummy non-through vias 162d when seen in the plan view as seen in the thickness direction of the multi-layered section 201 (e.g., the Z-axis direction) is preferably equal to or higher than 0.1%, and is more preferably equal to or higher than 1%, in a rectangular region SQ of 100 μm in length×100 μm in width which is located at any position in the chip region R1.

In addition, when seen in the plan view as seen in the thickness direction of the multi-layered section 201 (e.g., the Z-axis direction), a distance L between one dummy non-through via 162d and another dummy non-through via 162d that is adjacent to the one dummy non-through via 162d at the shortest distance is preferably equal to or shorter than 100 μm, and is more preferably equal to or shorter than 20 μm.

With this configuration, it becomes easier to cause atoms (e.g., H atoms) that terminate dangling bonds to move between the second substrate section 120 and the third substrate section 130 through the dummy non-through via units 160d. It becomes easier to make uniform the movement of atoms (e.g., H atoms) that terminate dangling bonds, between the second substrate section 120 and the third substrate section 130.

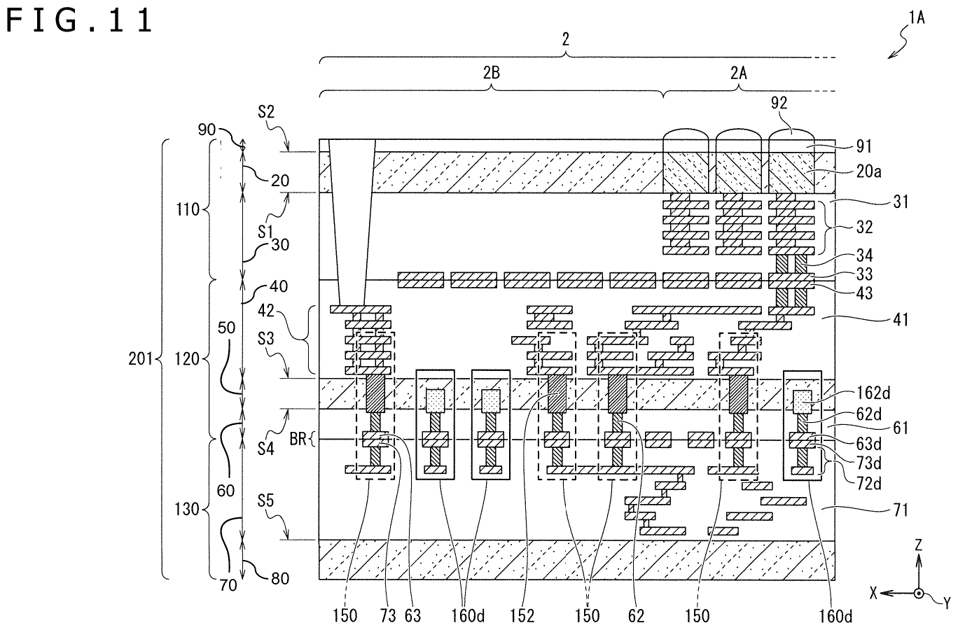

FIG. 11 is a cross-sectional view illustrating a configuration example of the multi-layered substrate 200A that is illustrated in FIG. 9 and that has been subjected to dicing. By dicing the multi-layered substrate 200A illustrated in FIG. 9 into the multiple chip regions R1, as illustrated in FIG. 11, the semiconductor chip 2 on which a light detecting device 1A is mounted can be obtained.

As explained above, according to the light detecting device 1A according to the second embodiment of the present disclosure, the dummy non-through vias 162d that the dummy non-through via units 160d have are arranged in the pixel region 2A and in the peripheral region 2B. In the multi-layered substrate 200A in which the light detecting device 1A is formed in a panelized manner, the dummy non-through vias 162d may further be arranged in the scribe region R2.

According to this, it is possible to cause atoms (e.g., H atoms) that terminate dangling bonds to move between the second substrate section 120 and the third substrate section 130 through the through via units 150 and the dummy non-through via units 160d. The movement, between the second substrate section 120 and the third substrate section 130, of atoms (e.g., H atoms) that terminate dangling bonds can be made uniform, and this can contribute to elimination of uneven distribution of atoms (e.g., H atoms) that terminate dangling bonds.

As a result, in field-effect transistors included in the second circuits and field-effect transistors included in third circuits, the threshold voltage (Vth) shift caused by the presence of atoms (e.g., H atoms) that terminate dangling bonds can be made uniform. Even in a case where the number of stacked layers of substrate sections is increased to three or more in the multi-layered substrate 200A or the light detecting device 1A obtained by dicing the multi-layered substrate 200A, degradation of characteristics of the light detecting device 1A can be prevented.

### Modification Example of Second Embodiment

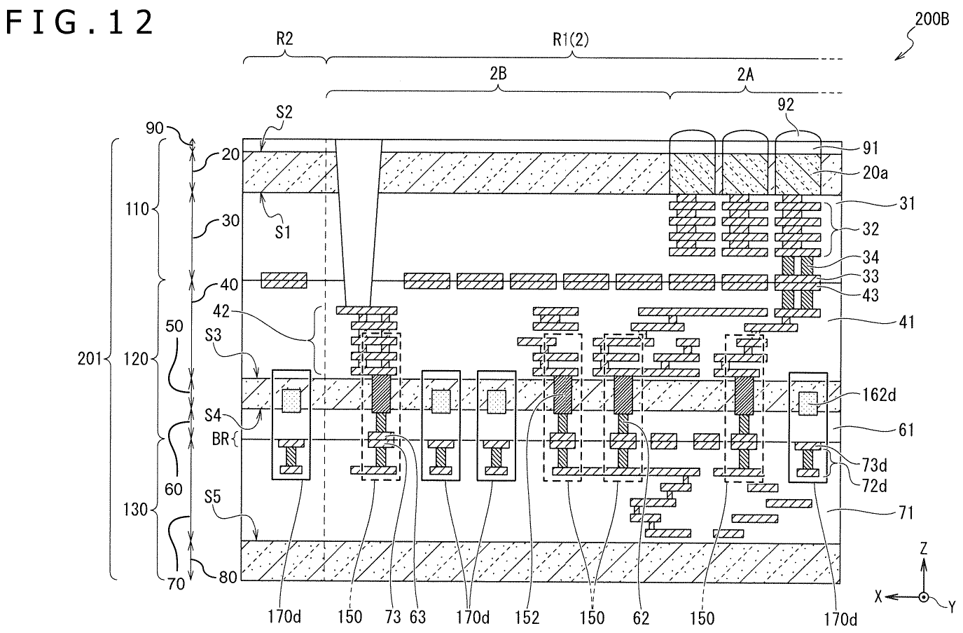

FIG. 12 is a cross-sectional view illustrating a configuration of a multi-layered substrate 200B according to a modification example of the second embodiment of the present disclosure. A difference between the multi-layered substrate 200B according to the modification example of the second embodiment and the multi-layered substrate 200A according to the second embodiment illustrated in FIG. 9 and the like resides in a configuration of the dummy non-through via units 160d.

As illustrated in FIG. 12, the multi-layered substrate 200B includes dummy non-through via units 170d (examples of the “dummy via units” of the present disclosure). The dummy non-through via units 170d have the dummy non-through vias 162d, the dummy connection pads 73d, and the dummy wires 72d. The dummy non-through via units 170d are not provided with the dummy wires 62d and the dummy connection pads 63d (see FIG. 9 for both of them).

Even with such a configuration, it is possible to cause atoms (e.g., H atoms) that terminate dangling bonds to move between the second substrate section 120 and the third substrate section 130 through the through via units 150 and the dummy non-through via units 170d. It is possible to make uniform the movement of atoms (e.g., H atoms) that terminate dangling bonds, between the second substrate section 120 and the third substrate section 130. As a result, even in a case where the number of stacked layers of substrate sections is increased to three or more, degradation of characteristics of the light detecting device can be prevented.

### Third Embodiment

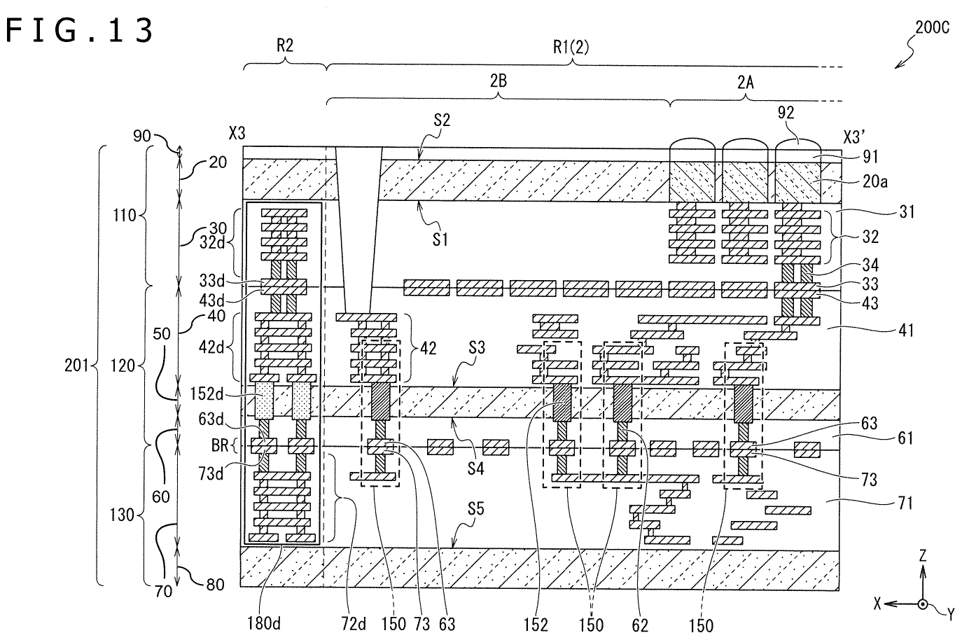

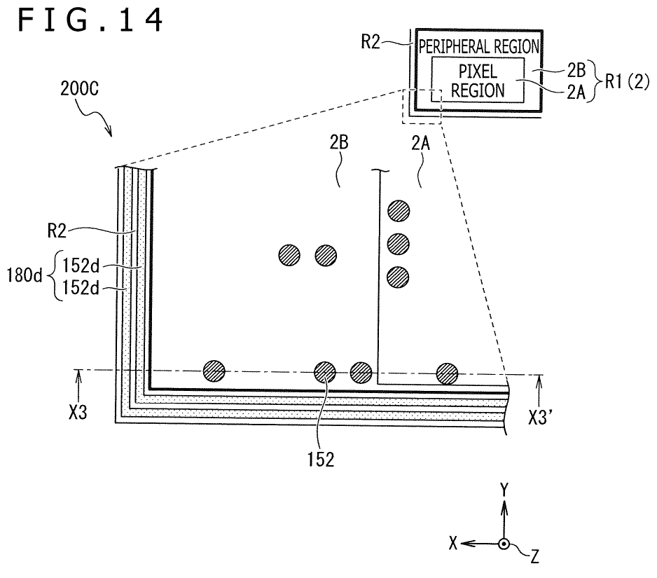

In an embodiment of the present disclosure, dummy via units may be arranged in the scribe region. FIG. 13 is a cross-sectional view illustrating a configuration example of a multi-layered substrate 200C according to a third embodiment of the present disclosure. FIG. 14 is a plan view illustrating an arrangement example of the through vias 152 and the dummy through vias 152d in the multi-layered substrate 200C according to the third embodiment of the present disclosure. Note that a cross-section taken along a line X3-X3′ in the plan view in FIG. 14 corresponds to the cross-sectional view in FIG. 13.

As illustrated in FIG. 13, the multi-layered substrate 200C according to the third embodiment of the present disclosure includes dummy through via units 180d (examples of the “dummy via units” of the present disclosure) arranged in the scribe region R2. The dummy through via units 180d are provided in the multi-layered section 201, are insulated from both the first circuits and the second circuits, and are electrically fixed at a floating or reference potential (e.g., a ground potential (0 V)).

The dummy through via units 180d have the dummy through vias 152d, the dummy wires 42d, 62d, and 72d, and the dummy connection pads 63d and 73d interconnecting the dummy wires 62d and 72d. In addition, the dummy through vias 152d have dummy wires 32d provided at the first substrate section 110, and dummy connection pads 33d and 43d interconnecting the dummy wires 32d and 42d. For example, the dummy connection pads 33d and 43d include Cu or a Cu alloy.

As illustrated in FIG. 14, the dummy through via units 180d are provided in the scribe region R2, and are arranged to continuously surround the chip region R1. For example, the dummy through vias 152d of the dummy through via units 180d are arranged to surround the chip region R1 in two layers. In addition, although not illustrated in FIG. 14, the dummy wires 32d, 42d, 62d, and 72d and the dummy connection pads 33d, 43d, 63d, and 73d that the dummy through via units 180d have are also arranged to surround the chip region R1 in two layers. With this configuration, the dummy through via units 180d are included in at least part of a guard ring surrounding the chip region R1.

Even with such a configuration, it is possible to cause atoms (e.g., H atoms) that terminate dangling bonds to move between the second substrate section 120 and the third substrate section 130 through the through via units 150 and the dummy through via units 180d. It is possible to make uniform the movement of atoms (e.g., H atoms) that terminate dangling bonds, between the second substrate section 120 and the third substrate section 130. As a result, even in a case where the number of stacked layers of substrate sections is increased to three or more, degradation of characteristics of the light detecting device can be prevented.

### Modification Example of Third Embodiment

Whereas the dummy through via units 180d are arranged to continuously surround the chip region R1 in the aspect illustrated in FIG. 13 and FIG. 14, the third embodiment of the present disclosure is not limited to this. The dummy through via units 180d may intermittently surround the chip region R1.

In addition, whereas the dummy through vias 152d of the dummy through via units 180d are arranged to surround the chip region R1 in two layers in the aspect illustrated in FIG. 13 and FIG. 14, the third embodiment of the present disclosure is not limited to this. The dummy through vias 152d may surround the chip region R1 in one layer or may surround the chip region R1 in three or more layers.

Further, in the third embodiment of the present disclosure, the dummy through via units 150d explained in the first embodiment, the dummy non-through via units 160d explained in the second embodiment, and the dummy non-through via units 170d explained in the modification example of the second embodiment may be arranged in the chip region R1.

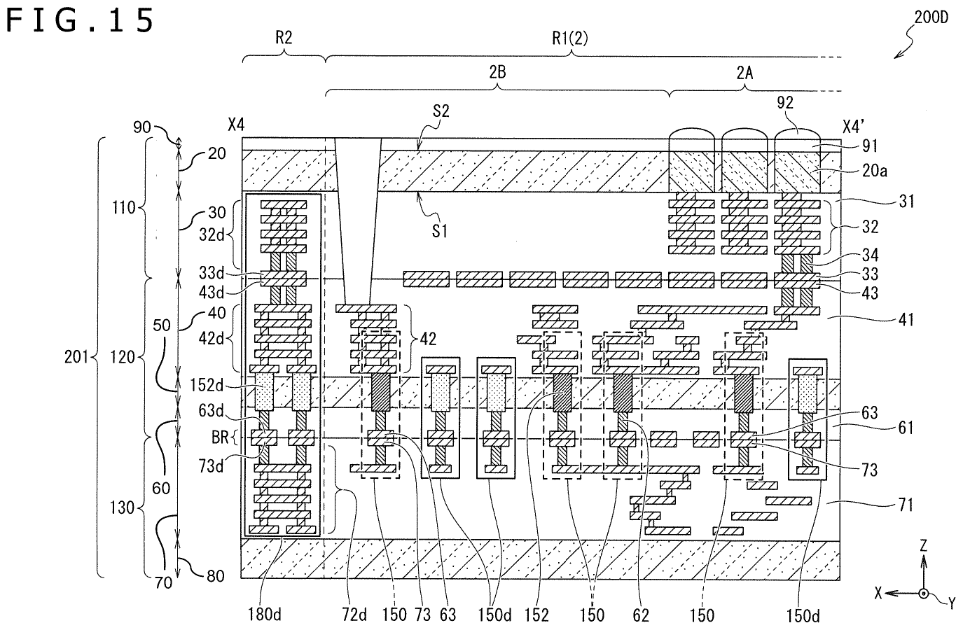

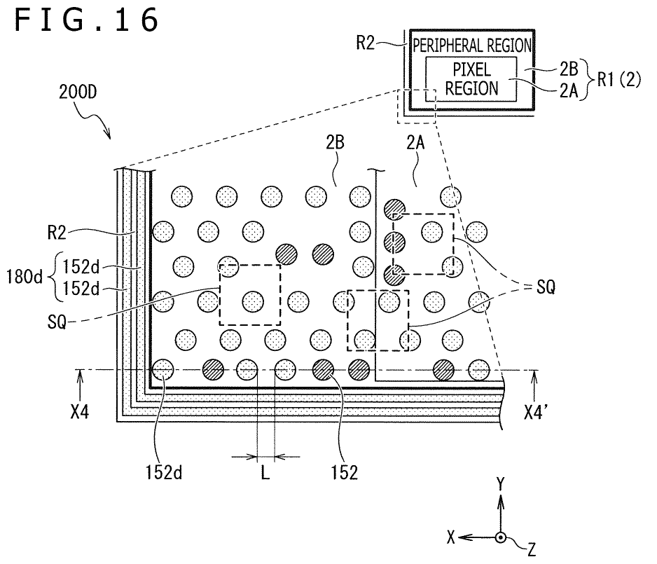

FIG. 15 is a cross-sectional view illustrating a configuration of a multi-layered substrate 200D according to a modification example of the third embodiment of the present disclosure. FIG. 16 is a plan view illustrating an arrangement example of the through vias 152 and dummy through via units 152d in the multi-layered substrate 200D according to the modification example of the third embodiment of the present disclosure. Note that a cross-section taken along a line X4-X4′ in the plan view in FIG. 16 corresponds to the cross-sectional view in FIG. 15.

As illustrated in FIG. 15 and FIG. 16, the multi-layered substrate 200D according to the modification example of the third embodiment of the present disclosure includes the dummy through via units 150d arranged in the chip region R1 and the dummy through via units 180d arranged in the scribe region R2.

According to this, it is possible to cause atoms (e.g., H atoms) that terminate dangling bonds to move between the second substrate section 120 and the third substrate section 130 through the through via units 150 and the dummy through via units 150d and 180d. It is possible to make more uniform the movement of atoms (e.g., H atoms) that terminate dangling bonds, between the second substrate section 120 and the third substrate section 130.

### Fourth Embodiment

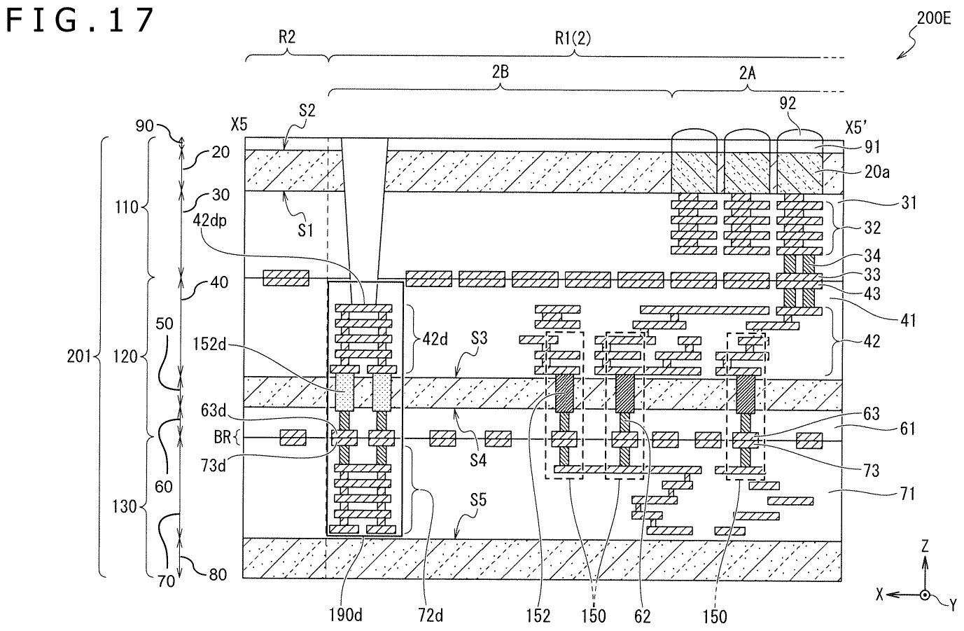

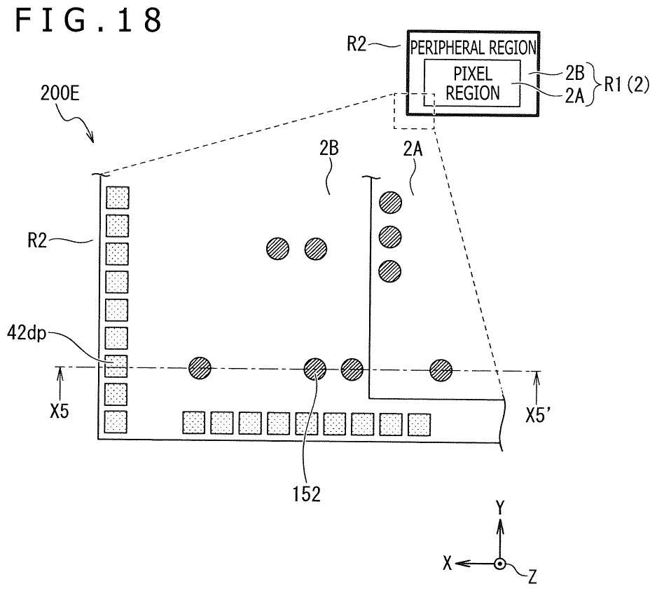

In an embodiment of the present disclosure, dummy via units may be arranged below bonding pads that can connect conductive wires such as gold wires to each other. FIG. 17 is a cross-sectional view illustrating a configuration example of a multi-layered substrate 200E according to a fourth embodiment of the present disclosure. FIG. 18 is a plan view illustrating an arrangement example of the through vias 152 and dummy bonding pads 42dp in the multi-layered substrate 200C according to the fourth embodiment of the present disclosure. Note that a cross-section taken along a line X5-X5′ in the plan view in FIG. 18 corresponds to the cross-sectional view in FIG. 17.

As illustrated in FIG. 17, the multi-layered substrate 200E according to the fourth embodiment of the present disclosure includes dummy through via units 190d (examples of the “dummy via units” of the present disclosure) arranged in the peripheral region 2B. The dummy through via units 190d are provided in the multi-layered section 201, are insulated from both the first circuits and the second circuits, and are electrically fixed at a floating or reference potential (e.g., a ground potential (0 V)).

The dummy through via units 190d have the dummy through vias 152d, the dummy wires 42d, 62d, and 72d, and the dummy connection pads 63d and 73d interconnecting the dummy wires 62d and 72d. One end (the upper end in FIG. 17) of each dummy through via 152d is connected to the dummy wire 42d, and the other end (the lower end in FIG. 17) of the dummy through via 152d is connected to the dummy wire 62d. A portion of the dummy wire 42d that is positioned on the uppermost layer is the dummy bonding pad 42dp. The dummy bonding pad 42dp may be or may not be connected with a conductive wire (not illustrated) such as a gold wire.

According to this, it is possible to cause atoms (e.g., H atoms) that terminate dangling bonds to move between the second substrate section 120 and the third substrate section 130 through the through via units 150 and the dummy through via units 190d. It is possible to make uniform the movement of atoms (e.g., H atoms) that terminate dangling bonds, between the second substrate section 120 and the third substrate section 130. As a result, even in a case where the number of stacked layers of substrate sections is increased to three or more, degradation of characteristics of the light detecting device can be prevented.

### Modification Example of Fourth Embodiment

In the fourth embodiment of the present disclosure, the dummy through via units 150d explained in the first embodiment, the dummy non-through via units 160d explained in the second embodiment, and the dummy non-through via units 170d explained in the modification example of the second embodiment may be arranged in the chip region R1. In addition, the dummy through via units 180d explained in the third embodiment may be arranged in the scribe region R2.

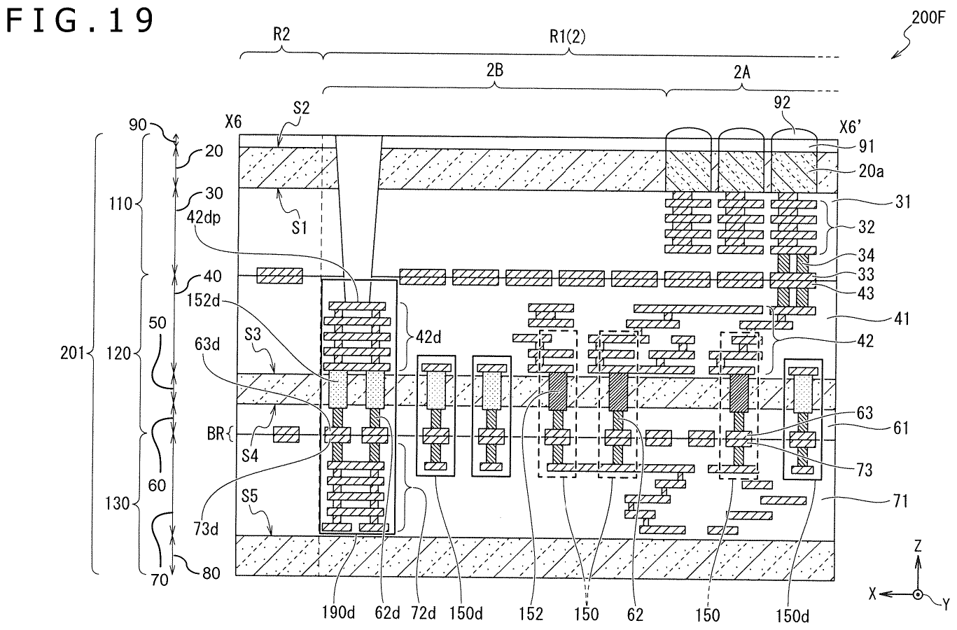

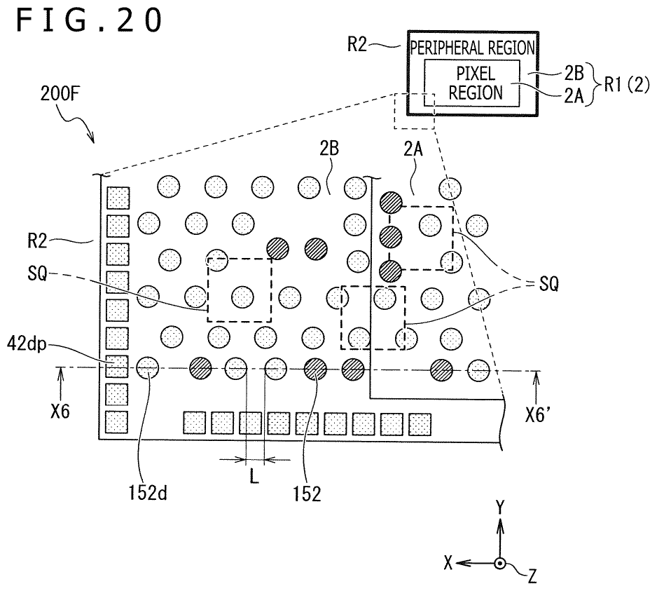

FIG. 19 is a cross-sectional view illustrating a configuration of a multi-layered substrate 200F according to a modification example of the fourth embodiment of the present disclosure. FIG. 20 is a plan view illustrating an arrangement example of the through vias 152, the dummy through vias 152d, and the dummy bonding pads 42dp in the multi-layered substrate 200F according to the modification example of the fourth embodiment of the present disclosure. Note that a cross-section taken along a line X6-X6′ in the plan view in FIG. 20 corresponds to the cross-sectional view in FIG. 19.

As illustrated in FIG. 19 and FIG. 20, the multi-layered substrate 200F according to the modification example of the fourth embodiment of the present disclosure includes the dummy through via units 150d arranged in the chip region R1, the dummy through via units 150d arranged in the chip region R1, and the dummy through via units 190d arranged in the peripheral region 2B in the chip region R1.

According to this, it is possible to cause atoms (e.g., H atoms) that terminate dangling bonds to move between the second substrate section 120 and the third substrate section 130 through the through via units 150 and the dummy through via units 150d and 190d. It is possible to make more uniform the movement of atoms (e.g., H atoms) that terminate dangling bonds, between the second substrate section 120 and the third substrate section 130.

### Fifth Embodiment

In an embodiment of the present disclosure, through via units electrically connecting the first circuits and the second circuits to each other may have barrier metal layers that inhibit the supply of hydrogen (H) atoms.

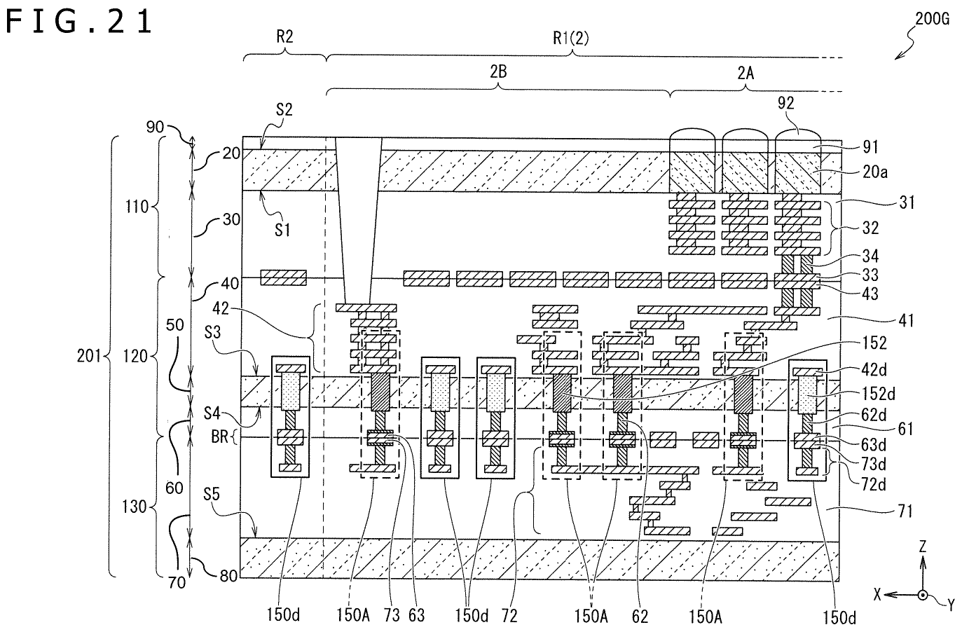

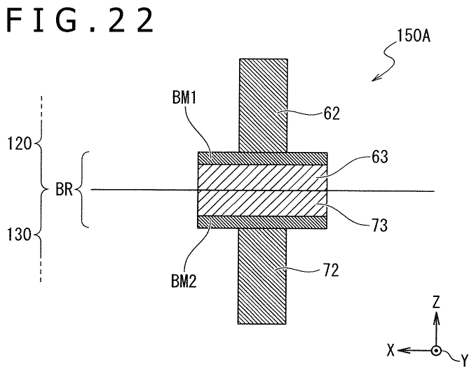

FIG. 21 is a cross-sectional view illustrating a configuration example of a multi-layered substrate 200G according to a fifth embodiment of the present disclosure. FIG. 22 is a cross-sectional view illustrating an enlarged view of barrier metal layers BM1 and BM2 of through via units 150A that the multi-layered substrate 200G according to the fifth embodiment of the present disclosure has.

As illustrated in FIG. 21, the multi-layered substrate 200G according to the fifth embodiment of the present disclosure includes the through via units 150A electrically connecting the first circuits provided at the second substrate section 120 and the second circuits provided at the third substrate section 130 to each other. As illustrated in FIG. 22, the through via units 150A have the barrier metal layers BM1 arranged between the connection pads 63 and the wires 62 and the barrier metal layers BM2 arranged between the connection pads 73 and the wires 72. For example, the barrier metal layers BM1 and BM2 are molybdenum silicide (MoSi) layers.

According to this, in the through via units 150, the barrier metal layers BM1 and BM2 prevent the movement of atoms (e.g., H atoms) that terminate dangling bonds. As a result, it is possible to prevent the threshold voltage (Vth) of a field-effect transistor from being shifted due to the movement of atoms (e.g., H atoms) that terminate dangling bonds.

### Other Embodiments

Whereas, as described above, the present disclosure has been described using the embodiments and the modification examples, statements and figures forming part of this disclosure should not be understood as limiting the present disclosure. Various alternative embodiments, implementation examples, and operational technologies will be apparent to those skilled in the art from this disclosure. Needless to say, the present technology includes various embodiments and the like not described here. Within the scope not departing from the gist of the embodiments and modification examples described above, at least one of various types of omission, replacement, and change of constituent elements can be performed. In addition, advantages described in the present specification are merely illustrated as examples, advantages of the present disclosure are not limited to them, and there may be other advantages.

### Example of Application to Endoscopic Surgery System

The technology according to the present disclosure (present technology) can be applied to various products. For example, the technology according to the present disclosure may be applied to an endoscopic surgery system.

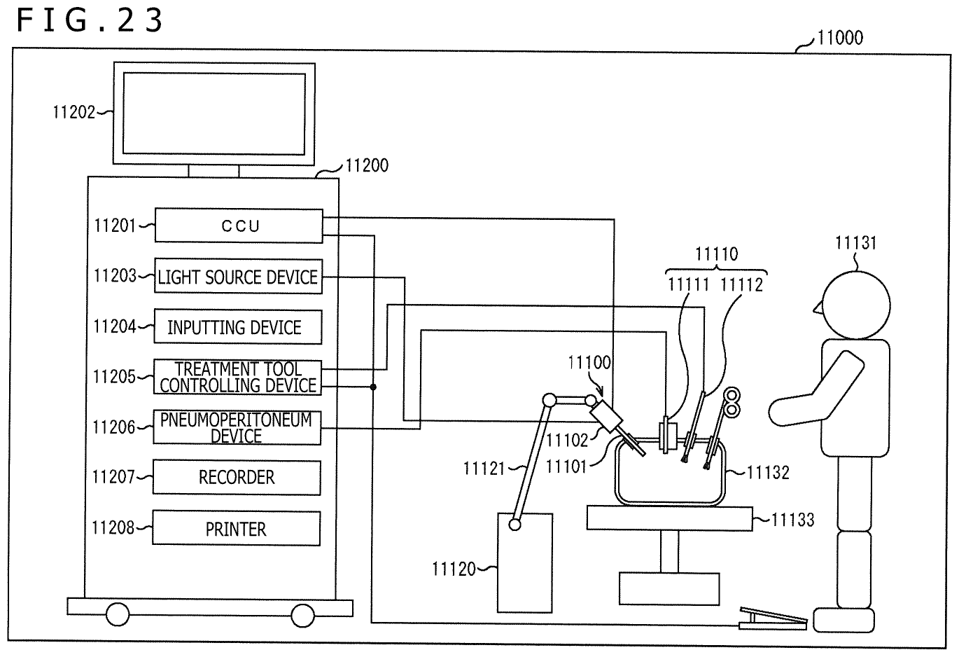

FIG. 23 is a view illustrating an example of a schematic configuration of an endoscopic surgery system to which the technology according to the present disclosure (present technology) can be applied.

In FIG. 23, a state is illustrated in which a surgeon (medical doctor) 11131 is using an endoscopic surgery system 11000 to perform surgery for a patient 11132 on a patient bed 11133. As illustrated, the endoscopic surgery system 11000 includes an endoscope 11100, other surgical tools 11110 such as a pneumoperitoneum tube 11111 and an energy treatment tool 11112, a supporting arm device 11120 which supports the endoscope 11100 thereon, and a cart 11200 on which various devices for endoscopic surgery are mounted.

The endoscope 11100 includes a lens barrel 11101 having a region of a predetermined length from a distal end thereof to be inserted into a body cavity of the patient 11132 and a camera head 11102 connected to a proximal end of the lens barrel 11101. In the example illustrated, the endoscope 11100 which includes as a rigid endoscope having the lens barrel 11101 of the hard type is illustrated. However, the endoscope 11100 may otherwise be included as a flexible endoscope having the lens barrel 11101 of the flexible type.

The lens barrel 11101 has, at a distal end thereof, an opening in which an objective lens is fitted. A light source device 11203 is connected to the endoscope 11100 such that light generated by the light source device 11203 is introduced to a distal end of the lens barrel 11101 by a light guide extending in the inside of the lens barrel 11101 and is applied toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an imaging element are provided in the inside of the camera head 11102 such that reflected light (observation light) from the observation target is condensed on the imaging element by the optical system. The observation light is photo-electrically converted by the imaging element to generate an electric signal corresponding to the observation light, namely, an image signal corresponding to an observation image. The image signal is transmitted as RAW data to a camera control unit (CCU) 11201.

The CCU 11201 includes a CPU (Central Processing Unit), a GPU (Graphics Processing Unit), or the like and integrally controls operation of the endoscope 11100 and a display device 11202. Further, the CCU 11201 receives an image signal from the camera head 11102 and performs, on the image signal, various types of image processes for displaying an image based on the image signal, such as a development process (demosaicing process), for example.

The display device 11202 displays thereon an image based on an image signal, for which the image processes have been performed by the CCU 11201, under the control of the CCU 11201.

The light source device 11203 includes a light source such as an LED (Light Emitting Diode), for example, and supplies irradiation light upon imaging of a surgical region to the endoscope 11100.

An inputting device 11204 is an input interface for the endoscopic surgery system 11000. A user can perform input of various types of information or input of an instruction to the endoscopic surgery system 11000 through the inputting device 11204. For example, the user inputs an instruction to change an imaging condition (type of irradiation light, magnification, focal distance, and the like) by the endoscope 11100, for example.

A treatment tool controlling device 11205 controls driving of the energy treatment tool 11112 for cautery or incision of a tissue, sealing of a blood vessel, or the like. A pneumoperitoneum device 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is a device capable of recording various types of information relating to surgery. A printer 11208 is a device capable of printing various types of information relating to surgery in various forms such as a text, an image, or a graph.

It is to be noted that the light source device 11203 which supplies irradiation light when a surgical region is to be imaged to the endoscope 11100 can include a white light source which includes, for example, an LED, a laser light source, or a combination of them. In a case where a white light source includes a combination of RGB laser light sources, since the output intensity and the output timing can be controlled with a high degree of accuracy for each color (each wavelength), adjustment of the white balance of a captured image can be performed by the light source device 11203. Further, in this case, if laser beams from the respective RGB laser light sources are applied time-divisionally to an observation target and driving of the imaging elements of the camera head 11102 are controlled in synchronism with the irradiation timings, images individually corresponding to the R, G, and B colors can also be captured time-divisionally. According to this method, a color image can be obtained even if color filters are not provided for the imaging element.

Further, the light source device 11203 may be controlled such that the intensity of light to be output is changed for each predetermined time. By controlling driving of the imaging element of the camera head 11102 in synchronism with the timing of the change of the intensity of light to acquire images time-divisionally and synthesizing the images, an image of a high dynamic range free from what are generally called underexposed blocked-up shadows and overexposed highlights can be generated.

Further, the light source device 11203 may be configured to supply light of a predetermined wavelength band suitable for special light observation. In special light observation, for example, by utilizing the wavelength dependency of absorption of light in a body tissue to apply light of a band which is narrow in comparison with irradiation light used in ordinary observation (namely, white light), narrow band observation (narrow band imaging) of imaging a predetermined tissue such as a blood vessel of a superficial portion of the mucous membrane in a high contrast is performed. Alternatively, in special light observation, fluorescent observation for obtaining an image from fluorescent light generated by application of excitation light may be performed. In fluorescent observation, it is possible to perform observation of fluorescent light from a body tissue by applying excitation light to the body tissue (autofluorescence observation) or to obtain a fluorescent light image by locally injecting a reagent such as indocyanine green (ICG) into a body tissue and applying excitation light corresponding to a fluorescent light wavelength of the reagent to the body tissue, for example. The light source device 11203 can be configured to supply such narrow-band light and/or excitation light suitable for special light observation as described above.

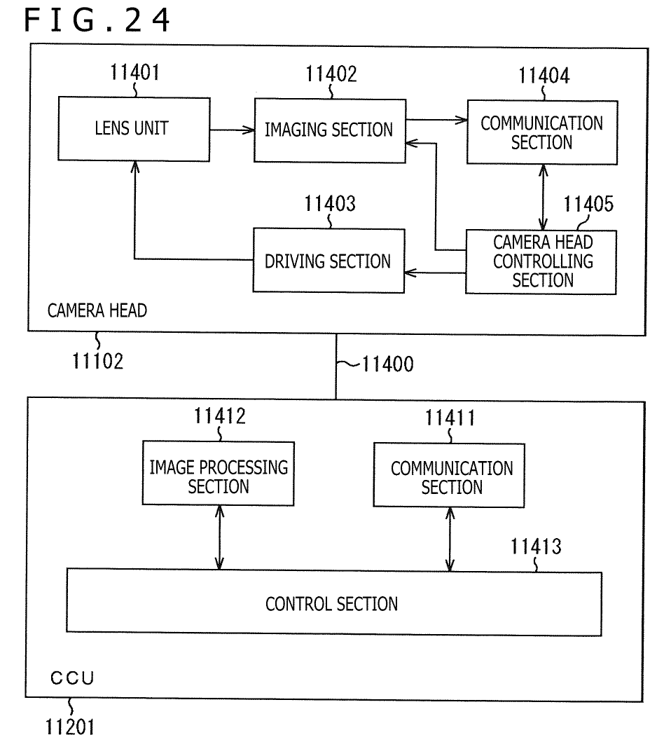

FIG. 24 is a block diagram illustrating an example of a functional configuration of the camera head 11102 and the CCU 11201 illustrated in FIG. 23.

The camera head 11102 includes a lens unit 11401, an imaging section 11402, a driving section 11403, a communication section 11404, and a camera head controlling section 11405. The CCU 11201 includes a communication section 11411, an image processing section 11412, and a control section 11413. The camera head 11102 and the CCU 11201 are connected for communication to each other by a transmission cable 11400.

The lens unit 11401 is an optical system provided at a connecting location to the lens barrel 11101. Observation light taken in from a distal end of the lens barrel 11101 is introduced to the camera head 11102 and enters the lens unit 11401. The lens unit 11401 includes a combination of multiple lenses including a zoom lens and a focusing lens.

The imaging section 11402 includes imaging elements. The number of imaging elements which is included in the imaging section 11402 may be one (what is generally called a single-plate type) or may be two or more (what is generally called a multi-plate type). In a case where the imaging section 11402 is configured as that of the multi-plate type, for example, image signals corresponding to respective R, G, and B may be generated by the imaging elements, and the image signals may be synthesized to obtain a color image. Alternatively, the imaging section 11402 may also include a pair of imaging elements for acquiring respective image signals for the right eye and the left eye suitable for 3D (Dimensional) display. If 3D display is performed, then the depth of a living body tissue in a surgical region can be recognized more accurately by the surgeon 11131. It is to be noted that, in a case where the imaging section 11402 is configured as that of the multi-plate type, multiple systems of lens units 11401 can be provided corresponding to the individual imaging elements.

Further, the imaging section 11402 may not necessarily be provided on the camera head 11102. For example, the imaging section 11402 may be provided immediately behind the objective lens in the inside of the lens barrel 11101.

The driving section 11403 includes an actuator and moves the zoom lens and the focusing lens of the lens unit 11401 by a predetermined distance along an optical axis under the control of the camera head controlling section 11405. Consequently, the magnification and the focal point of an image captured by the imaging section 11402 can be adjusted suitably.

The communication section 11404 includes a communication device for transmitting and receiving various types of information to and from the CCU 11201. The communication section 11404 transmits, as RAW data, an image signal acquired from the imaging section 11402 to the CCU 11201 through the transmission cable 11400.

In addition, the communication section 11404 receives a control signal for controlling driving of the camera head 11102 from the CCU 11201 and supplies the control signal to the camera head controlling section 11405. The control signal includes information relating to imaging conditions such as information indicating a frame rate for a captured image, information indicating an exposure value at the time of imaging, and/or information indicating a magnification and a focal point of a captured image, for example.

It is to be noted that the imaging conditions such as the frame rate, the exposure value, the magnification, or the focal point may be designated by the user or may be set automatically by the control section 11413 of the CCU 11201 on the basis of an acquired image signal. In the latter case, what are generally called an AE (Auto Exposure) function, an AF (Auto Focus) function, and an AWB (Auto White Balance) function are incorporated in the endoscope 11100.

The camera head controlling section 11405 controls driving of the camera head 11102 on the basis of a control signal received from the CCU 11201 through the communication section 11404.

The communication section 11411 includes a communication device for transmitting and receiving various types of information to and from the camera head 11102. The communication section 11411 receives an image signal transmitted thereto from the camera head 11102 through the transmission cable 11400.

Further, the communication section 11411 transmits a control signal for controlling driving of the camera head 11102 to the camera head 11102. The image signal and the control signal can be transmitted by electrical communication, optical communication, or the like.

The image processing section 11412 performs various image types of processes on an image signal in the form of RAW data transmitted thereto from the camera head 11102.

The control section 11413 performs various types of control relating to imaging of a surgical region or the like by the endoscope 11100 and display of a captured image obtained by imaging of the surgical region or the like. For example, the control section 11413 generates a control signal for controlling driving of the camera head 11102.

Further, the control section 11413 causes, on the basis of an image signal on which image processes have been performed by the image processing section 11412, the display device 11202 to display a captured image in which the surgical region or the like is imaged. At this time, the control section 11413 may recognize various types of objects in the captured image by using various types of image recognition technologies. For example, the control section 11413 can recognize a surgical tool such as forceps, a particular living body region, bleeding, mist occurring when the energy treatment tool 11112 is used, and so forth by detecting the shape, color, and so forth of edges of objects included in a captured image. The control section 11413 may cause, when it causes the display device 11202 to display a captured image, various types of surgery supporting information to be displayed in an overlapping manner with an image of the surgical region, by using a result of the recognition. When surgery supporting information is displayed in an overlapping manner and presented to the surgeon 11131, the burden on the surgeon 11131 can be reduced, and the surgeon 11131 can proceed with the surgery with certainty.

The transmission cable 11400 which connects the camera head 11102 and the CCU 11201 to each other is an electric signal cable suitable for communication of an electric signal, an optical fiber suitable for optical communication, or a composite cable suitable for both of electrical and optical communications.

Here, while, in the example illustrated, communication is performed by wired communication using the transmission cable 11400, the communication between the camera head 11102 and the CCU 11201 may be performed by wireless communication.

An example of an endoscopic surgery system to which the technology according to the present disclosure can be applied has been explained thus far. The technology according to the present disclosure can be applied to the endoscope 11100, (the imaging section 11402 of) the camera head 11102, (the image processing section 11412 of) the CCU 11201, and the like, for example, in the configuration explained above. Specifically, light detecting devices (e.g., the light detecting devices 1 and 1A) that are obtained by dicing the multi-layered substrate 200, 200A, 200B, 200C, 200D, 200E, 200F, and 200G can be applied to the imaging section 10402.

Note that, whereas an endoscopic surgery system has been explained as an example here, the technology according to the present disclosure may be applied to other systems such as a microscopic surgery system, for example.

### Example of Application to Mobile Body

The technology according to the present disclosure (present technology) can be applied to various products. For example, the technology according to the present disclosure may be realized as a device to be mounted on any type of mobile body such as an automobile, an electric automobile, a hybrid electric automobile, a motorcycle, a bicycle, a personal mobility, an airplane, a drone, a ship, or a robot.

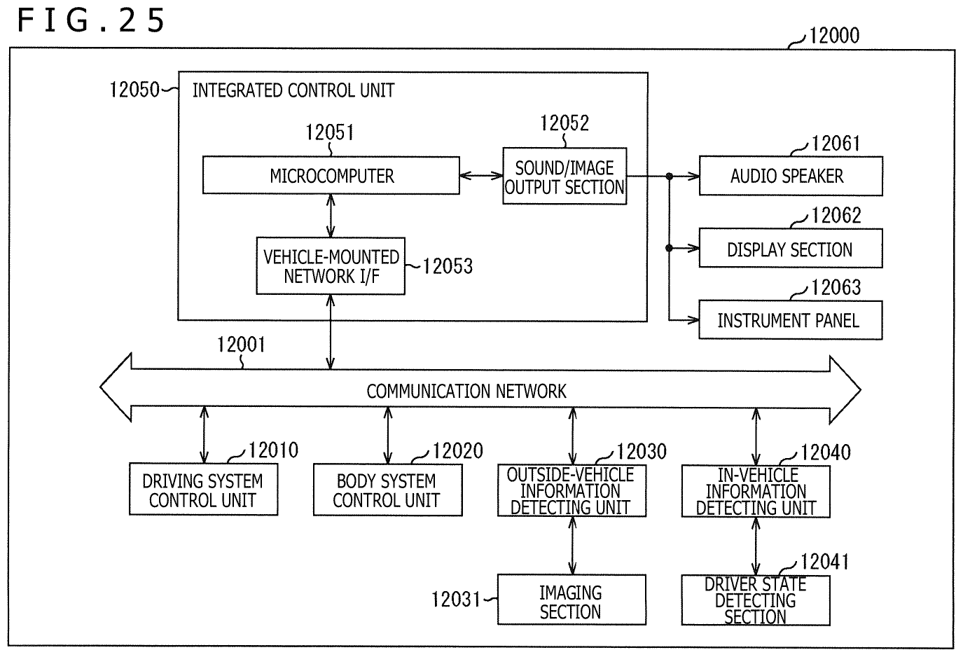

FIG. 25 is a block diagram illustrating an example of a schematic configuration of a vehicle control system as an example of a mobile body control system to which the technology according to the present disclosure can be applied.

The vehicle control system 12000 includes multiple electronic control units connected to each other via a communication network 12001. In the example illustrated in FIG. 25, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network I/F (interface) 12053 are illustrated as a functional configuration of the integrated control unit 12050.

The driving system control unit 12010 controls the operation of devices related to the driving system of the vehicle in accordance with various types of programs. For example, the driving system control unit 12010 functions as a control device for a driving force generating device for generating the driving force of the vehicle, such as an internal combustion engine or a driving motor, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various types of devices provided to a vehicle body in accordance with various types of programs. For example, the body system control unit 12020 functions as a control device for a keyless entry system, a smart key system, a power window device, or various types of lamps such as a headlamp, a backup lamp, a brake lamp, a turn signal, or a fog lamp. In this case, radio waves transmitted from a mobile device as an alternative to a key or signals of various types of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information regarding the outside of the vehicle including the vehicle control system 12000. For example, the outside-vehicle information detecting unit 12030 is connected with an imaging section 12031. The outside-vehicle information detecting unit 12030 makes the imaging section 12031 capture an image of the outside of the vehicle, and receives the captured image. On the basis of the received image, the outside-vehicle information detecting unit 12030 may perform processing of detecting an object such as a human, a vehicle, an obstacle, a sign, or a character on a road surface or processing of detecting a distance thereto.

The imaging section 12031 is an optical sensor that receives light and outputs an electric signal corresponding to a received light amount of the light. The imaging section 12031 can output the electric signal as an image, or can output the electric signal as information regarding a measured distance. In addition, the light received by the imaging section 12031 may be visible light, or may be invisible light such as infrared rays.

The in-vehicle information detecting unit 12040 detects information regarding the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information regarding the inside or outside of the vehicle obtained by the outside-vehicle information detecting unit 12030 or the in-vehicle information detecting unit 12040, and output a control command to the driving system control unit 12010. For example, the microcomputer 12051 can perform cooperative control intended to implement functions of an ADAS (Advanced Driver Assistance System), the functions including collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for, for example, automated driving, which makes the vehicle to travel automatedly without depending on the operation of the driver, by controlling the driving force generating device, the steering mechanism, the braking device, or the like on the basis of the information regarding the outside or inside of the vehicle obtained by the outside-vehicle information detecting unit 12030 or the in-vehicle information detecting unit 12040.

In addition, the microcomputer 12051 can output a control command to the body system control unit 12020 on the basis of the information regarding the outside of the vehicle obtained by the outside-vehicle information detecting unit 12030. For example, the microcomputer 12051 can perform cooperative control intended to prevent a glare by controlling the headlamp to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying an occupant of the vehicle or the outside of the vehicle of information. In the example of FIG. 25, an audio speaker 12061, a display section 12062, and an instrument panel 12063 are illustrated as the output device. The display section 12062 may, for example, include at least one of an on-board display and a head-up display.

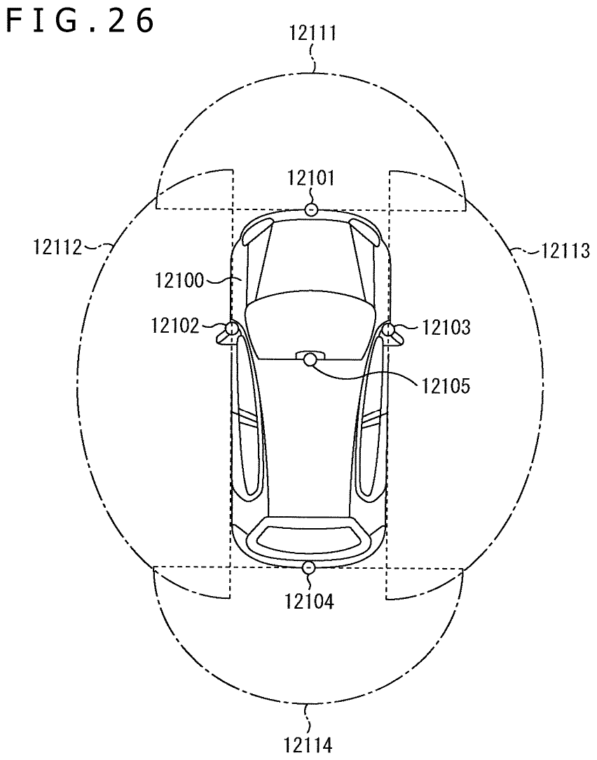

FIG. 26 is a diagram illustrating an example of the installation position of the imaging section 12031.

In FIG. 26, a vehicle 12100 includes, as the imaging section 12031, imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle, for example. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The image of the front obtained by the imaging section 12101 and the imaging section 12105 is used mainly to detect a preceding vehicle, a pedestrian, an obstacle, a signal, a traffic sign, a lane, or the like.

Incidentally, FIG. 26 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera including multiple imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and that travels in substantially the same direction as that of the vehicle 12100 at a predetermined speed (for example, equal to or more than 0 km/h). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for, for example, automated driving that makes the vehicle travel automatedly without depending on the operation of the driver.

For example, the microcomputer 12051 can classify three-dimensional object data regarding three-dimensional objects into three-dimensional object data regarding a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in images captured by the imaging sections 12101 to 12104. Such recognition of a pedestrian is, for example, performed by a procedure of extracting characteristic points in the images captured by the imaging sections 12101 to 12104 as infrared cameras and a procedure of determining whether or not it is the pedestrian by performing pattern matching processing on a series of characteristic points representing the contour of the object.

When the microcomputer 12051 determines that there is a pedestrian in the images captured by the imaging sections 12101 to 12104 and thus recognizes the pedestrian, the sound/image output section 12052 controls the display section 12062 such that a square contour line for emphasis is displayed in such a manner as to be superimposed on the recognized pedestrian. Further, the sound/image output section 12052 may also control the display section 12062 such that an icon or the like representing the pedestrian is displayed at a desired position.

An example of a vehicle control system to which the technology according to the present disclosure can be applied has been explained thus far. The technology according to the present disclosure can be applied to the imaging section 12031 and the like in the configuration explained above. Specifically, light detecting devices (e.g., the light detecting devices 1 and 1A) that are obtained by dicing the multi-layered substrate 200, 200A, 200B, 200C, 200D, 200E, 200F, and 200G can be applied to the imaging section 12031.

Note that the present disclosure can also adopt configurations like the ones below.
(1) A light detecting device including:
a multi-layered section having a first substrate section, a second substrate section provided on a side of one surface of the first substrate section, and a third substrate section provided on the side of the one surface of the first substrate section with the second substrate section interposed therebetween;
multiple through via units that are provided in the multi-layered section and electrically connect a first circuit provided at the second substrate section and a second circuit provided at the third substrate section to each other; and
multiple dummy via units that are provided in the multi-layered section, are insulated from both the first circuit and the second circuit, and are electrically fixed at a floating or reference potential, in which
the multi-layered section has
   a pixel region, and
   a peripheral region positioned at a periphery of the pixel region when seen in a plan view as seen in a thickness direction of the multi-layered section,
the first substrate section has
   a first semiconductor layer that has a first surface and a second surface positioned on a side opposite to the first surface and is provided with a photo-electric converting element, and
   a first wiring layer provided on a side of the first surface of the first semiconductor layer,
the second substrate section has
   a second semiconductor layer having a third surface facing the first semiconductor layer and a fourth surface positioned on a side opposite to the third surface,
   a second wiring layer provided on a side of the third surface of the second semiconductor layer, and
   a third wiring layer provided on a side of the fourth surface of the second semiconductor layer,
each of the through via units has a through via penetrating from the third surface to the fourth surface of the second semiconductor layer,
each of the dummy via units has a dummy via at least partially buried in the second semiconductor layer, and
the dummy vias are arranged in the pixel region and in the peripheral region.
(2) The light detecting device according to (1) above, in which
the dummy vias include dummy through vias penetrating from the third surface to the fourth surface of the second semiconductor layer.
(3) The light detecting device according to (2) above, in which
the third substrate section has
   a third semiconductor layer having a fifth surface facing the second semiconductor layer, and
   a fourth wiring layer provided on a side of the fifth surface of the third semiconductor layer, and
each of the dummy vias has
   a first dummy wire provided in the second wiring layer and connected to one end of the dummy through via,
   a second dummy wire provided in the third wiring layer and connected to another end of the dummy through via,
   a third dummy wire provided in the fourth wiring layer, and
   a dummy connection pad that is provided at a boundary section between the third wiring layer and the fourth wiring layer, connects the second dummy wire and the third dummy wire to each other, and bonds the second substrate section and the third substrate section to each other.
(4) The light detecting device according to (3) above, in which
the dummy connection pad has
   a first dummy connection pad provided on a side of the third wiring layer relative to the boundary section, and
   a second dummy connection pad provided on a side of the fourth wiring layer relative to the boundary section, and
the first dummy connection pad and the second dummy connection pad each include copper (Cu) or a Cu alloy.
(5) The light detecting device according to any one of (1) to (4) above, in which
the third substrate section has
   a third semiconductor layer having a fifth surface facing the second semiconductor layer, and
   a fourth wiring layer provided on a side of the fifth surface of the third semiconductor layer, and
each of the through via units has
   a first wire provided in the second wiring layer and connected to one end of the through via,
   a second wire provided in the third wiring layer and connected to another end of the through via,
   a third wire provided in the fourth wiring layer, and
   a connection pad that is provided at a boundary section between the third wiring layer and the fourth wiring layer, connects the second wire and the third wire to each other, and bonds the second substrate section and the third substrate section to each other.
(6) The light detecting device according to (5) above, in which
the connection pad has
   a first connection pad provided on a side of the third wiring layer relative to the boundary section, and
   a second connection pad provided on a side of the fourth wiring layer relative to the boundary section, and
the first connection pad and the second connection pad each include copper (Cu) or a Cu alloy.
(7) The light detecting device according to (6) above, in which
each of the through via units has a barrier metal layer between the first connection pad and the second wire and/or between the second connection pad and the third wire.
(8) The light detecting device according to (7) above, in which
the barrier metal layer includes molybdenum silicide (MoSi).
(9) The light detecting device according to any one of (1) to (8) above, in which
an area density of the dummy vias when seen in the plan view as seen in the thickness direction of the multi-layered section is equal to or higher than 0.1% in a rectangular region of 100 μm in length×100 μm in width which is located at any position in a region that includes at least one of the pixel region and the peripheral region.
(10) The light detecting device according to any one of (1) to (9) above, in which,
when seen in the plan view as seen in the thickness direction of the multi-layered section, a distance between one and another of the dummy vias that are adjacent to each other at a shortest distance is equal to or shorter than 100 μm.
(11) The light detecting device according to any one of (1) to (10) above, further including:
an optical lens that is arranged opposite the second substrate section with the first substrate section interposed therebetween and condenses incident light that is incident on the first substrate section onto the photo-electric converting element.
(12) The light detecting device according to (11) above, in which
the optical lens is arranged in the pixel region, but is not arranged in the peripheral region.
(13) A multi-layered substrate including:
a multi-layered section having a first substrate section, a second substrate section provided on a side of one surface of the first substrate section, and a third substrate section provided on the side of the one surface of the first substrate section with the second substrate section interposed therebetween;
multiple through via units that are provided in the multi-layered section and electrically connect a first circuit provided at the second substrate section and a second circuit provided at the third substrate section to each other; and
multiple dummy via units that are provided in the multi-layered section, are insulated from both the first circuit and the second circuit, and are electrically fixed at a floating or reference potential, in which
the multi-layered section has
   a pixel region,
   a peripheral region positioned at a periphery of the pixel region when seen in a plan view as seen in a thickness direction of the multi-layered section, and
   a scribe region positioned outside the pixel region with the peripheral region interposed therebetween,
the first substrate section has
   a first semiconductor layer that has a first surface and a second surface positioned on a side opposite to the first surface and is provided with a photo-electric converting element, and
   a first wiring layer provided on a side of the first surface of the first semiconductor layer,
the second substrate section has
   a second semiconductor layer having a third surface facing the first semiconductor layer and a fourth surface positioned on a side opposite to the third surface,
   a second wiring layer provided on a side of the third surface of the second semiconductor layer, and
   a third wiring layer provided on a side of the fourth surface of the second semiconductor layer,
each of the through via units has a through via penetrating from the third surface to the fourth surface of the second semiconductor layer,
each of the dummy via units has a dummy via at least partially buried in the second semiconductor layer, and
the dummy vias are arranged in the pixel region and in the peripheral region.
(14) The multi-layered substrate according to (13) above, in which
the dummy vias are arranged in the scribe region.

### REFERENCE SIGNS LIST

1, 1A: Light detecting device
2: Semiconductor chip
2A: Pixel region
2B: Peripheral region
3: Pixel
4: Vertical drive circuit
5: Column signal processing circuit
6: Horizontal drive circuit
7: Output circuit
8: Control circuit
10: Pixel driving line
11: Vertical signal line
12: Horizontal signal line
13: Logic circuit
14: Bonding pad
15: Readout circuit
20: First semiconductor layer
20a: Photo-electric conversion region
20b: Separation region
30: First wiring layer
31, 41, 61, 71: Insulating film
32, 42, 62, 72: Wire
32d, 42d, 62d, 72d: Dummy wire
33, 43, 63, 73: Connection pad
33d, 43d, 63d, 73d: Dummy connection pad
34, 44, 74: Via (contact)
40: Second wiring layer
42dp: Dummy bonding pad
42dP: Dummy bonding pad
50: Second semiconductor layer
50a: First region
50b: Second region
51: First conductor
52: Second conductor
60: Third wiring layer
65: Silicon cover film
70: Fourth wiring layer
80: Third semiconductor layer
90: Light-condensing layer
91: Color filter
92: On-chip lens
110: First substrate section
120: Second substrate section
130: Third substrate section
150, 150A: Through via unit
150d, 180d, 190d: Dummy through via unit
152: Through via
152d: Dummy through via
160d, 170d: Dummy non-through via unit
162d: Dummy non-through via
200, 200A, 200B, 200C, 200D, 200E, 200F, 200G: Multi-layered substrate
201: Multi-layered section
10402: Imaging section
11000: Endoscopic surgery system
11100: Endoscope
11101: Lens barrel
11102: Camera head
11110: Surgical tool
11111: Pneumoperitoneum tube
11112: Energy treatment tool
11120: Supporting arm device
11131: Surgeon (doctor)
11132: Patient
11133: Patient bed
11200: Cart
11201: Camera control unit (CCU)
11202: Display device
11203: Light source device
11204: Inputting device
11205: Treatment tool controlling device
11206: Pneumoperitoneum device
11207: Recorder
11208: Printer
11400: Transmission cable
11401: Lens unit
11402: Imaging section
11403: Driving section
11404: Communication section
11405: Camera head controlling section
11411: Communication section
11412: Image processing section
11413: Control section
12000: Vehicle control system
12001: Communication network
12010: Driving system control unit
12020: Body system control unit
12030: Outside-vehicle information detecting unit
12031: Imaging section
12040: In-vehicle information detecting unit
12041: Driver state detecting section
12050: Integrated control unit
12051: Microcomputer
12052: /und/ image output section
12061: Audio speaker
12062: Display section
12063: Instrument panel
12100: Vehicle
12101, 12102, 12103, 12104, 12105: Imaging section
12111, 12112, 12113, 12114: Imaging range
AMP: Amplification transistor
AMP: Transistor
BM1, BM2: Barrier metal layer
BR: Boundary section
CCU11201: Camera head
FD: Electric charge accumulation region
I: In-vehicle network
ICG: Indocyanine green
PD: Photo-electric converting element
R1: Chip region
R2: Scribe region
RST: Reset transistor
S1, S3, S5: Main surface
S2, S4: Back surface
SEL: Selection transistor
SQ: Rectangular region
T1, T2, T3: Transistor
TR: Transfer transistor
TSV: Through-silicon via
Vdd: Power line
VSL: Vertical signal line
Vth: Threshold voltage

What is claimed is:

1. A light detecting device comprising:
a multi-layered section having a first substrate section, a second substrate section provided on a side of one surface of the first substrate section, and a third substrate section provided on the side of the one surface of the first substrate section with the second substrate section interposed therebetween;
multiple through via units that are provided in the multi-layered section and electrically connect a first circuit provided at the second substrate section and a second circuit provided at the third substrate section to each other; and
multiple dummy via units that are provided in the multi-layered section, are insulated from both the first circuit and the second circuit, and are electrically fixed at a floating or reference potential, wherein
the multi-layered section has
a pixel region, and
a peripheral region positioned at a periphery of the pixel region when seen in a plan view as seen in a thickness direction of the multi-layered section,
the first substrate section has
a first semiconductor layer that has a first surface and a second surface positioned on a side opposite to the first surface and is provided with a photo-electric converting element, and
a first wiring layer provided on a side of the first surface of the first semiconductor layer,
the second substrate section has
a second semiconductor layer having a third surface facing the first semiconductor layer and a fourth surface positioned on a side opposite to the third surface,
a second wiring layer provided on a side of the third surface of the second semiconductor layer, and
a third wiring layer provided on a side of the fourth surface of the second semiconductor layer,
each of the through via units has a through via penetrating from the third surface to the fourth surface of the second semiconductor layer,
each of the dummy via units has a dummy via at least partially buried in the second semiconductor layer, and
the dummy vias are arranged in the pixel region and in the peripheral region.

2. The light detecting device according to claim 1, wherein
the dummy vias include dummy through vias penetrating from the third surface to the fourth surface of the second semiconductor layer.

3. The light detecting device according to claim 2, wherein
the third substrate section has
a third semiconductor layer having a fifth surface facing the second semiconductor layer, and
a fourth wiring layer provided on a side of the fifth surface of the third semiconductor layer, and
each of the dummy vias has
a first dummy wire provided in the second wiring layer and connected to one end of the dummy through via,
a second dummy wire provided in the third wiring layer and connected to another end of the dummy through via,
a third dummy wire provided in the fourth wiring layer, and
a dummy connection pad that is provided at a boundary section between the third wiring layer and the fourth wiring layer, connects the second dummy wire and the third dummy wire to each other, and bonds the second substrate section and the third substrate section to each other.

4. The light detecting device according to claim 3, wherein
the dummy connection pad has
a first dummy connection pad provided on a side of the third wiring layer relative to the boundary section, and
a second dummy connection pad provided on a side of the fourth wiring layer relative to the boundary section, and
the first dummy connection pad and the second dummy connection pad each include copper (Cu) or a Cu alloy.

5. The light detecting device according to claim 1, wherein
the third substrate section has
a third semiconductor layer having a fifth surface facing the second semiconductor layer, and
a fourth wiring layer provided on a side of the fifth surface of the third semiconductor layer, and
each of the through via units has
a first wire provided in the second wiring layer and connected to one end of the through via,
a second wire provided in the third wiring layer and connected to another end of the through via,
a third wire provided in the fourth wiring layer, and
a connection pad that is provided at a boundary section between the third wiring layer and the fourth wiring layer, connects the second wire and the third wire to each other, and bonds the second substrate section and the third substrate section to each other.

6. The light detecting device according to claim 5, wherein
the connection pad has
a first connection pad provided on a side of the third wiring layer relative to the boundary section, and
a second connection pad provided on a side of the fourth wiring layer relative to the boundary section, and
the first connection pad and the second connection pad each include copper (Cu) or a Cu alloy.

7. The light detecting device according to claim 6, wherein
each of the through via units has a barrier metal layer between the first connection pad and the second wire and/or between the second connection pad and the third wire.

8. The light detecting device according to claim 7, wherein
the barrier metal layer includes molybdenum silicide (MoSi).

9. The light detecting device according to claim 1, wherein
an area density of the dummy vias when seen in the plan view as seen in the thickness direction of the multi-layered section is equal to or higher than 0.1% in a rectangular region of 100 μm in length×100 μm in width which is located at any position in a region that includes at least one of the pixel region and the peripheral region.

10. The light detecting device according to claim 1, wherein,
when seen in the plan view as seen in the thickness direction of the multi-layered section, a distance between one and another of the dummy vias that are adjacent to each other at a shortest distance is equal to or shorter than 100 μm.

11. The light detecting device according to claim 1, further comprising:
an optical lens that is arranged opposite the second substrate section with the first substrate section interposed therebetween and condenses incident light that is incident on the first substrate section onto the photo-electric converting element.

12. The light detecting device according to claim 11, wherein
the optical lens is arranged in the pixel region, but is not arranged in the peripheral region.

13. A multi-layered substrate comprising:
a multi-layered section having a first substrate section, a second substrate section provided on a side of one surface of the first substrate section, and a third substrate section provided on the side of the one surface of the first substrate section with the second substrate section interposed therebetween;
multiple through via units that are provided in the multi-layered section and electrically connect a first circuit provided at the second substrate section and a second circuit provided at the third substrate section to each other; and
multiple dummy via units that are provided in the multi-layered section, are insulated from both the first circuit and the second circuit, and are electrically fixed at a floating or reference potential, wherein
the multi-layered section has
a pixel region,
a peripheral region positioned at a periphery of the pixel region when seen in a plan view as seen in a thickness direction of the multi-layered section, and
a scribe region positioned outside the pixel region with the peripheral region interposed therebetween,
the first substrate section has
a first semiconductor layer that has a first surface and a second surface positioned on a side opposite to the first surface and is provided with a photo-electric converting element, and
a first wiring layer provided on a side of the first surface of the first semiconductor layer,
the second substrate section has
a second semiconductor layer having a third surface facing the first semiconductor layer and a fourth surface positioned on a side opposite to the third surface,
a second wiring layer provided on a side of the third surface of the second semiconductor layer, and
a third wiring layer provided on a side of the fourth surface of the second semiconductor layer,
each of the through via units has a through via penetrating from the third surface to the fourth surface of the second semiconductor layer,
each of the dummy via units has a dummy via at least partially buried in the second semiconductor layer, and
the dummy vias are arranged in the pixel region and in the peripheral region.

14. The multi-layered substrate according to claim 13, wherein
the dummy vias are arranged in the scribe region.
